(19) United States
(12) Patent Application Publication
(10) Pub. No.: US 2022/0344588 A1
(43) Pub. Date: Oct. 27, 2022

(54) ELECTRON TRANSPORT COMPOSITION, LIGHT-EMITTING ELEMENT MANUFACTURED THROUGH THE SAME, AND METHOD OF MANUFACTURING THE LIGHT-EMITTING ELEMENT

(71) Applicant: Samsung Display Co., Ltd., Yongin-si (KR)

(72) Inventors: SANGHEE YU, Hwaseong-si (KR); GYUBONG KIM, Suwon-si (KR); HOI-LIM KIM, Seoul (KR); SUNGWOON KIM, Hwaseong-si (KR); HYUNMI DOH, Seoul (KR); JAE HONG PARK, Seoul (KR); SEIHWAN AHN, Hwaseong-si (KR)

(21) Appl. No.: 17/697,663

(22) Filed: Mar. 17, 2022

(30) Foreign Application Priority Data
Apr. 14, 2021 (KR) 10-2021-0048131

(51) Int. Cl. H01L 51/00; C09K 11/02

(52) U.S. Cl. CPC H01L 51/005; C09K 11/02; H01L 51/0067; H01L 51/502

(57) ABSTRACT

An electron transport composition includes a metal oxide and a photoacid generator, wherein the photoacid generator has at least one of a halogenated triazine-based compound or an oxime sulfonate-based compound. When the electron transport composition is applied to a light-emitting element, the light-emitting element may exhibit improved luminous efficiency characteristics and element lifespan characteristics.

### CROSS-REFERENCE TO RELATED APPLICATION

This application claims priority to and the benefit of Korean Patent Application No. 10-2021-0048131, filed on Apr. 14, 2021, the entire content of which is hereby incorporated by reference.

### BACKGROUND

One or more embodiments of the present disclosure herein relate to an electron transport composition, a light-emitting element manufactured through (e.g., utilizing) the same, and a method of manufacturing the light-emitting element.

Various display devices used in multimedia devices such as a television, a mobile phone, a tablet computer, a navigation system, and/or a game console are being developed. In such display devices, a self-luminous display element is used that achieves display of images by causing a light-emitting material containing an organic compound to emit light.

In addition, development of a light-emitting element using quantum dots as a light-emitting material is in progress in order to improve the color reproducibility of a display device, and there is a need (or desire) to improve the luminous efficiency and lifespan of a light-emitting element using quantum dots.

### SUMMARY

One or more aspects of embodiments of the present disclosure are directed toward an electron transport composition that may be used in an electron transport region of a light-emitting element to exhibit an improved luminous efficiency and lifespan characteristics.

One or more aspects of embodiments of the present disclosure are also directed toward a light-emitting element having an improved luminous efficiency and lifespan by including, in an electron transport region, a metal oxide, and an acid and a conjugate base of the acid which are formed by decomposition of a photoacid generator.

One or more aspects of embodiments of the present disclosure are also directed toward a method of manufacturing a light-emitting element having an improved luminous efficiency and lifespan by applying an electron transport composition containing a metal oxide and a photoacid generator.

One or more embodiments of the present disclosure provide an electron transport composition including: a metal oxide; and a photoacid generator, wherein the photoacid generator includes at least one of a halogenated triazine-based compound or an oxime sulfonate-based compound.

In one or more embodiments, the photoacid generator may be represented by Formula 1 or Formula 2 below:

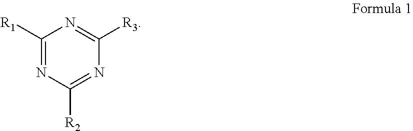

In Formula 1, R₁ to R₃ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least any one selected from among R₁ to R₃ may be CX₃, and X may be a halogen atom.

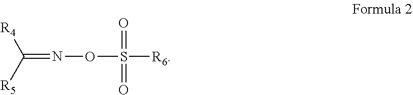

In Formula 2, R₄ and R₅ may be each independently a hydrogen atom, a deuterium atom, a halogen atom, a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and R₆ may be a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

In one or more embodiments, the metal oxide may include at least any one selected from among silicon, aluminum, zinc, indium, gallium, yttrium, germanium, scandium, titanium, tantalum, hafnium, zirconium, cerium, molybdenum, nickel, chromium, iron, niobium, tungsten, tin, copper, and mixtures thereof.

In one or more embodiments, a mass ratio of the photoacid generator to the metal oxide may be about 0.0001:1 to about 0.05:1.

In one or more embodiments, the electron transport composition may further include a solvent.

In one or more embodiments, the electron transport composition may further include a weak acid having a pKa of about 4.75 or higher, wherein a mass ratio of the photoacid generator to the weak acid may be about 0.01:1 to about 100:1.

In one or more embodiments of the present disclosure, a method of manufacturing a light-emitting element, the method includes: forming a hole transport region on a first electrode; forming a light-emitting layer on the hole transport region; forming an electron transport region on the light-emitting layer; and forming a second electrode on the electron transport region, wherein the forming of the electron transport region includes preparing an electron transport composition having a metal oxide and a photoacid generator; forming a preliminary electron transport region by applying the electron transport composition on the light-emitting layer, and irradiating the preliminary electron transport region with light, wherein the photoacid generator contains at least one of a halogenated triazine-based compound or an oxime sulfonate-based compound.

In one or more embodiments, the forming of the electron transport region may further include heat-treating the preliminary electron transport region at a first temperature.

In one or more embodiments, the heat-treating of the preliminary electron transport region at a first temperature may be performed before or after the irradiating the preliminary electron transport region with light.

In one or more embodiments, the method of manufacturing a light-emitting element may further include performing aging at a second temperature lower than the first temperature after the irradiating the preliminary electron transport region with light.

In one or more embodiments, the photoacid generator may be represented by Formula 1 or Formula 2 below:

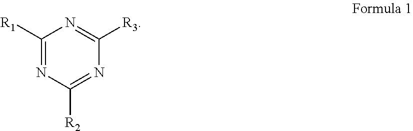

In Formula 1, R₁ to R₃ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least any one selected from among R₁ to R₃ may be CX₃, and X may be a halogen atom.

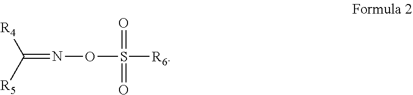

In Formula 2, R₄ and R₅ may be each independently a hydrogen atom, a deuterium atom, a halogen atom, a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and R₆ may be a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

In one or more embodiments, the light-emitting layer may include quantum dots.

In one or more embodiments, each of the quantum dots may include a core and a shell around the core.

In one or more embodiments, a mass ratio of the photoacid generator to the metal oxide may be about 0.0001:1 to about 0.05:1.

In one or more embodiments, the metal oxide may contain at least any one selected from among silicon, aluminum, zinc, indium, gallium, yttrium, germanium, scandium, titanium, tantalum, hafnium, zirconium, cerium, molybdenum, nickel, chromium, iron, niobium, tungsten, tin, copper, and mixtures thereof.

In one or more embodiments, the electron transport composition may further comprise a weak acid having a pKa of about 4.75 or higher, and a mass ratio of the photoacid generator to the weak acid may be about 0.01:1 to about 100:1.

In one or more embodiments of the present disclosure, a light-emitting element includes: a first electrode; a hole transport region disposed on the first electrode; a light-emitting layer disposed on the hole transport region and including quantum dots; an electron transport region disposed on the light-emitting layer; and a second electrode disposed on the electron transport region, wherein the electron transport region contains: a metal oxide; and an acid and a conjugate base of the acid which are generated by decomposition of a photoacid generator.

In one or more embodiments, the conjugate base may be represented by Formula 3 or Formula 4 below:

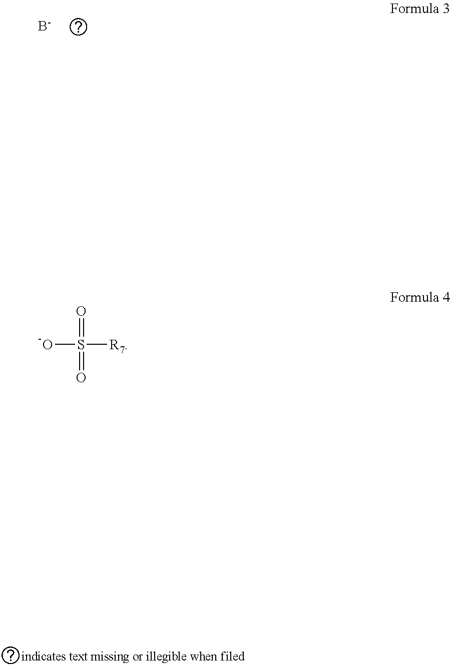

In Formulae 3 and 4, B may be a halogen atom, and R₇ may be a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

In one or more embodiments, the photoacid generator may include at least one of a halogenated triazine-based compound or an oxime sulfonate-based compound.

In one or more embodiments, the photoacid generator may be represented by Formula 1 or Formula 2 below:

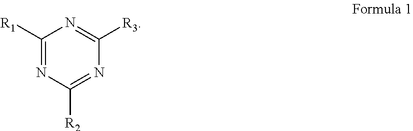

In Formula 1, R₁ to R₃ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, at least any one selected from among R₁ to R₃ may be CX₃, and X may be a halogen atom.

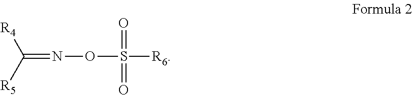

In Formula 2, R₄ and R₅ may be each independently a hydrogen atom, a deuterium atom, a halogen atom, a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and R₆ may be a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view illustrating an electronic apparatus EA according to one or more embodiments;

FIG. 2 is an exploded perspective view of an electronic apparatus EA according to one or more embodiments;

FIG. 3 is a cross-sectional view, of a display device DD according to one or more embodiments of the present disclosure, taken along line I-I′ of FIG. 2;

FIG. 4 is a plan view illustrating a display device according to one or more embodiments;

FIG. 5 is a cross-sectional view of a display device DD according to one or more embodiments;

FIGS. 6-9 are cross-sectional views of a light-emitting element according to one or more embodiments of the present disclosure;

FIG. 10 is a flowchart illustrating a method of manufacturing a light-emitting element according to one or more embodiments;

FIG. 11 is a flowchart in which an act of forming of an electron transport region according to one or more embodiments is subdivided into acts;

FIG. 12 is a diagram schematically illustrating an electron transport composition according to one or more embodiments;

FIGS. 13 and 14 are diagrams schematically illustrating some of the operations (or acts) of a method of manufacturing a light-emitting element according to one or more embodiments;

FIG. 15 is a schematic diagram illustrating some of the operations (or acts) of a method of manufacturing a light-emitting element according to one or more embodiments;

FIG. 16 is a schematic diagram illustrating some of the operations (or acts) of a method of manufacturing a light-emitting element according to one or more embodiments;

FIG. 17 is a diagram illustrating a reaction occurring in the electron transport composition; and

FIG. 18 is a graph showing a change in the degree of n-doping according to the number of hydrogen ions adsorbed onto the surface of a metal oxide according to one or more embodiments.

### DETAILED DESCRIPTION

As the present disclosure allows for various changes and numerous embodiments, some of the embodiments will be illustrated in the drawings and described in more detail in the present disclosure. However, this is not intended to limit the present disclosure to the specific disclosed form, it should be understood to include all modifications, equivalents, and substitutes included in the spirit and scope of the present disclosure.

It will be understood that when an element or layer is referred to as being “on”, “connected to” or “coupled to” another element or layer, it can be directly on, connected or coupled to the other element or layer or intervening elements or layers may be present.

In the present application, “directly disposed” (or “directly on, connected or coupled to”) means that there is no layer, film, region, plate, or the like added between the portion of the layer, film, and region. For example, “directly disposed” may mean disposing without additional members such as adhesive members between two layers or two members.

Like numbers refer to like elements throughout. The thickness and the ratio and the dimension of the elements shown in the drawings are exaggerated for effective description of the technical contents. In the present specification, the term “and/or” includes any and all combinations of one or more of the associated listed items. Further, the use of “may” when describing embodiments of the present disclosure refers to “one or more embodiments of the present disclosure.”

The terms first, second, etc. may be used to describe various elements, but the elements should not be limited by the terms. The terms are used only for the purpose of distinguishing one component from another. For example, without departing from the scope of the present disclosure, the first component may be referred to as a second component, and similarly, the second component may also be referred to as a first component. Singular expressions include plural expressions unless the context clearly indicates otherwise.

In addition, terms such as “below”, “under”, “above”, “on”, etc. are used to describe the relationship between the components shown in the drawings. The terms are relative concepts and are explained based on the directions indicated in the drawings.

Unless otherwise defined, all terms (including technical and scientific terms) used herein have the same meaning as commonly understood by one of ordinary skill in the art to which this invention belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “comprise,” “include,” or “have” are intended to indicate the presence of a feature, number, step, action, component, part, or combination thereof described in the specification, one or more other features, numbers, or steps. It should be understood that it does not preclude the existence or addition possibility of a feature, number, step, action, component, part, or combination thereof.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinafter, an electron transport composition, a light-emitting element manufactured using the same, and a method of manufacturing the light-emitting element will be described with reference to the accompanying drawings.

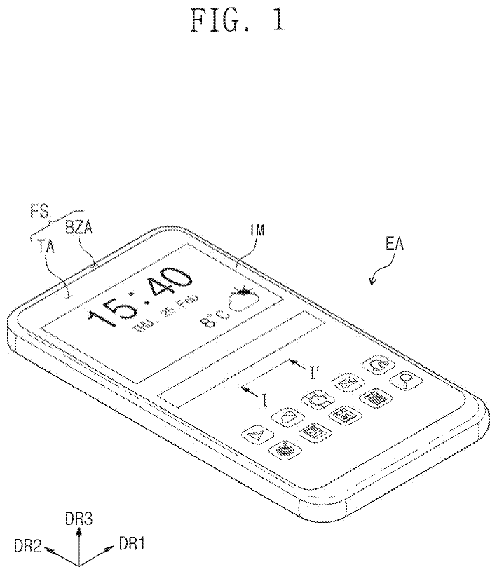

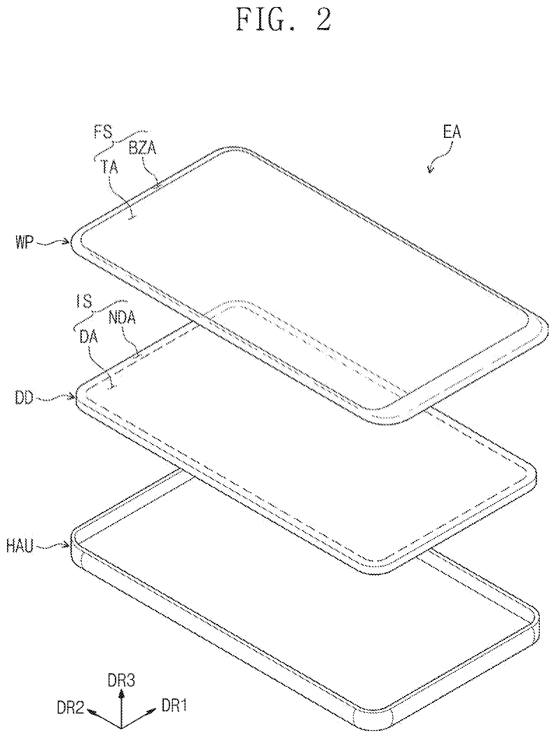

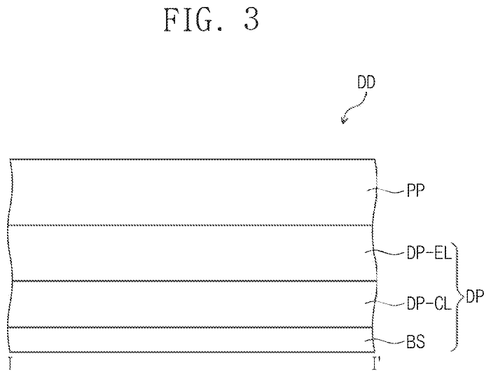

FIG. 1 is a perspective view illustrating an electronic apparatus EA according to one or more embodiments. FIG. 2 is an exploded perspective view of an electronic apparatus EA according to one or more embodiments. FIG. 3 is a cross-sectional view, of a display device DD according to one or more embodiments of the present disclosure, taken along line I-I′ of FIG. 2.

In one or more embodiments, an electronic apparatus EA may be a large-sized electronic apparatus such as a television, a monitor, and/or an external billboard. In addition, the electronic apparatus EA may be a small- and/or medium-sized electronic apparatus such as a personal computer, a notebook computer, a personal digital terminal, a car navigation unit, a game machine, a smartphone, a tablet computer, and/or a camera. However, these are presented only as examples, so that the electronic apparatus EA may employ other suitable electronic apparatuses without departing from the present disclosure. In the present embodiments, the electronic apparatus EA is illustrated as a smartphone, as an example.

The electronic apparatus EA may include a display device DD and a housing HAU. The display device DD may display an image IM through a display surface IS.

FIG. 1 illustrates that the display surface IS is parallel (or substantially parallel) to a plane defined by a first direction DR1 and a second direction DR2 intersecting the first direction DR1. However, this is an example, and in other embodiments, the display surface IS of the display device DD may have a curved shape.

The normal (e.g., perpendicular) direction of the display surface IS, e.g., a direction, in which the image IM is displayed, in the thickness direction of the display device DD, is indicated by a third direction DR3. A front surface (or upper surface) and a rear surface (or lower surface) of each member may be defined by the third direction DR3.

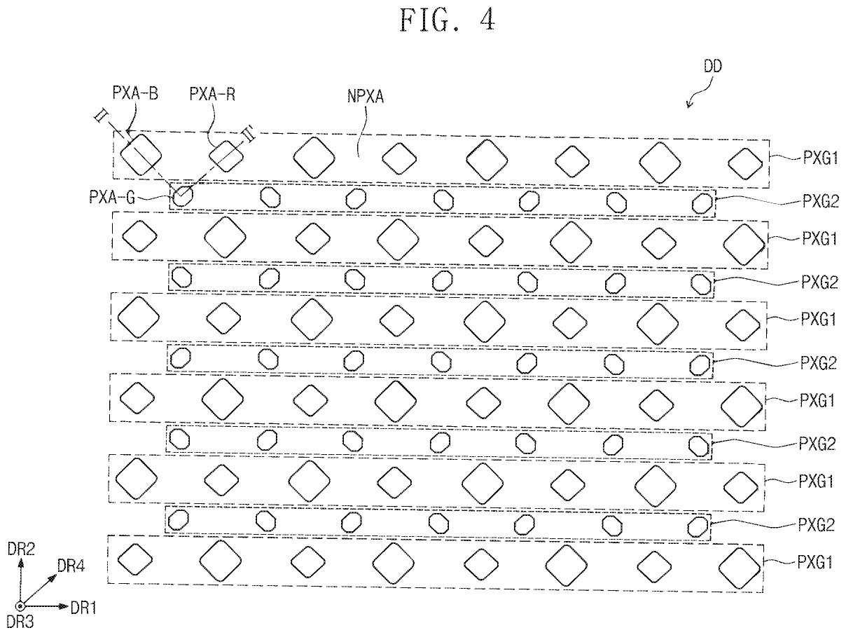

A fourth direction DR4 (see FIG. 4) may be a direction between the first direction DR1 and the second direction DR2. The fourth direction DR4 may be positioned on a plane parallel to a plane defined by the first direction DR1 and the second direction DR2. However, the directions indicated by the first to fourth directions DR1, DR2, DR3, and DR4 are relative concepts and may be changed to other directions.

The display surface FS on which the image IM is displayed in the electronic apparatus EA may correspond to a front surface of the display device DD, and may correspond to a front surface FS of a window WP. Hereinafter, the display surface and front surface of the electronic apparatus EA, and the front surface of the window WP are denoted as the same reference symbol. The image IM may include a dynamic image as well as a still image. In one or more embodiments, the electronic apparatus EA may include a foldable display device including a folding region and a non-folding region, and/or a bendable display device including at least one bendable part.

The housing HAU may accommodate the display device DD. The housing HAU may be disposed to cover the display device DD such that an upper surface of the display device DD, which is the display surface IS, is exposed. The housing HAU may cover a side surface and a bottom surface of the display device DD, and may expose an entire upper surface of the display device DD. However, one or more embodiments of the present disclosure are not limited thereto, and the housing HAU may cover not only the side surface and the bottom surface of the display device DD, but also a part of the upper surface.

In the electronic apparatus EA according to one or more embodiments, the window WP may include an optically transparent insulating material. The window WP may include a transmission region TA and a bezel region BZA. The front surface FS of the window WP including the transmission region TA and the bezel region BZA corresponds to the front surface FS of the electronic apparatus EA. A user may visually recognize an image provided through the transmission region TA corresponding to the front surface FS of the electronic apparatus EA.

FIGS. 1 and 2 illustrate that the transmission region TA has a rectangular shape with rounded vertices. However, this configuration is illustrated as an example, and the transmission region TA may have various suitable shapes, and one or more embodiments of the present disclosure are not limited to any one example.

The transmission region TA may be an optically transparent region. The bezel region BZA may have a relatively lower light transmittance than the transmission region TA. The bezel region BZA may have a predetermined or set color. The bezel region BZA may be adjacent to the transmission region TA and may surround the transmission region TA. The bezel region BZA may define the shape of the transmission region TA. However, one or more embodiments of the present disclosure are not limited to the illustrated one, and the bezel region BZA may be disposed adjacent to only one side of the transmission region TA, or a portion of the bezel region BZA may be omitted.

The display device DD may be disposed below the window WP. In the present specification, “below” may mean a direction opposite to a direction in which the display device DD provides an image.

In one or more embodiments, the display device DD may have a configuration that substantially generates an image IM. The image IM generated by the display device DD is displayed on the display surface IS, and is visually recognized by a user from the outside through the transmission region TA. The display device DD includes a display region DA and a non-display region NDA. The display region DA may be a region that is activated in response to an electrical signal. The non-display region NDA may be a region covered by the bezel region BZA. The non-display region NDA is adjacent to the display region DA. The non-display region NDA may surround (or be around) the display region DA.

The display device DD may include a display panel DP and an optical member PP disposed on the display panel DP. The display panel DP may include a display element layer DP-EL. The display element layer DP-EL includes a light-emitting element ED.

The display device DD may include a plurality of light-emitting elements ED-1, ED-2, and ED-3 (see FIG. 5). The light optical member PP may be disposed on the display panel DP to control reflected light of external light at the display panel DP. For example, the optical member PP may include a polarizing layer and/or a color filter layer.

In the display device DD according to one or more embodiments, the display panel DP may be a light-emitting display panel. For example, the display panel DP may be a quantum dot light-emitting display panel including a quantum dot light-emitting element. However, one or more embodiments of the present disclosure are not limited thereto, and the display panel DP may be an organic light-emitting display panel including an organic electroluminescent element.

The display panel DP may include a base substrate BS, a circuit layer DP-CL disposed on the base substrate BS, and a display element layer DP-EL disposed on the circuit layer DP-CL.

The base substrate BS may be a member that provides a base surface on which the display element layer DP-EL is disposed. The base substrate BS may be a glass substrate, a metal substrate, a plastic substrate, and/or the like. However, one or more embodiments of the present disclosure are not limited thereto, and the base substrate BS may be an inorganic layer, an organic layer, or a composite material layer (e.g., including an organic material and an inorganic material). The base substrate BS may be a flexible substrate that may be easily bendable and/or foldable.

In one or more embodiments, the circuit layer DP-CL may be disposed on the base substrate BS, and the circuit layer DP-CL may include a plurality of transistors. For example, the circuit layer DP-CL may include a switching transistor and a driving transistor for driving the light-emitting element ED of the display element layer DP-EL.

FIG. 4 is a plan view illustrating a display device DD according to one or more embodiments. FIG. 5 is a cross-sectional view of a display device DD according to one or more embodiments. FIG. 5 is a cross-sectional view taken along line II-II′ of FIG. 4.

Referring to FIGS. 4 and 5, the display device DD according to one or more embodiments includes a plurality of light-emitting elements ED-1, ED-2, and ED-3. In addition, the display device DD according to one or more embodiments may include a display panel DP having a plurality of light-emitting elements ED-1, ED-2, and ED-3, and an optical member PP disposed on display panel DP. In one or more embodiments, the optical member PP may be omitted in the display device DD according to one or more embodiments.

The display panel DP may include a base substrate BS, and a circuit layer DP-CL and a display element layer DP-EL which are provided on the base substrate BS. The display element layer DP-EL may include pixel defining layers PDL, light-emitting elements ED-1, ED-2, and ED-3 disposed between (or defined by) the pixel defining layers PDL, and an encapsulation layer TFE disposed on the light-emitting elements ED-1, ED-2, and ED-3.

The display device DD may include a peripheral region NPXA and light-emitting regions PXA-B, PXA-G, and PXA-R. The light-emitting regions PXA-B, PXA-G, and PXA-R may be respectively regions in which light generated by the light-emitting elements ED-1, ED-2, and ED-3 is respectively emitted. The light-emitting regions PXA-B, PXA-G, and PXA-R may be spaced apart from each other on a plane (e.g., in plan view).

The light-emitting regions PXA-B, PXA-G, and PXA-R may be divided into a plurality of groups according to the color of light generated from the light-emitting elements ED-1, ED-2, and ED-3. In the display device DD according to one or more embodiments illustrated in FIGS. 4 and 5, three light-emitting regions PXA-B, PXA-G, and PXA-R respectively emitting blue light, green light, and red light are exemplarily illustrated. For example, the display device DD according to one or more embodiments may include a blue light-emitting region PXA-B, a green light-emitting region PXA-G, and a red light-emitting region PXA-R that are distinguished from each other.

The plurality of light-emitting elements ED-1, ED-2, and ED-3 may emit light of different wavelength ranges. For example, in one or more embodiments, the display device DD may include a first light-emitting element ED-1 that is to emit blue light, a second light-emitting element ED-2 that is to emit green light, and a third light-emitting element ED-3 that is to emit red light. However, one or more embodiments of the present disclosure are not limited thereto, and the first to third light-emitting elements ED-1, ED-2, and ED-3 may emit light of the same wavelength range or at least one of the first to third light-emitting elements ED-1, ED-2, or ED-3 may emit light of a different wavelength range.

For example, the blue light-emitting region PXA-B, the green light-emitting region PXA-G, and the red light-emitting region PXA-R of the display device DD may respectively correspond to the first light-emitting element ED-1, the second light-emitting element ED-2, and the third light-emitting element ED-3.

The display device DD according to one or more embodiments may include a plurality of light-emitting elements ED-1, ED-2, and ED-3, and the light-emitting elements ED-1, ED-2, and ED-3 may include light-emitting layers EML-B, EML-G, and EML-R containing quantum dots QD1, QD2, and QD3, respectively.

The first light-emitting layer EML-B of the first light-emitting element ED-1 may include a first quantum dot QD1. The first quantum dot QD1 may emit blue light, which is first light. The second light-emitting layer EML-G of the second light-emitting element ED-2 and the third light-emitting layer EML-R of the third light-emitting element ED-3 may respectively include a second quantum dot QD2 and a third quantum dot QD3. The second quantum dot QD2 and the third quantum dot QD3 may respectively emit green light which is second light, and red light which is third light.

In one or more embodiments, the first light may be light having a center wavelength in a wavelength range of about 410 nm to about 480 nm, the second light may be light having a center wavelength in a wavelength range of about 500 nm to about 570 nm, and the third light may be light having a center wavelength in a wavelength range of about 625 nm to about 675 nm.

The quantum dots QD1, QD2, and QD3 included in the light-emitting layer EML-B, EML-G, and EML-R according to one or more embodiments may be a semiconductor nanocrystal that may be selected from among a group II-VI compound, a group III-VI compound, a group I-III-VI compound, a group III-V compound, a group III-II-V compound, a group IV-VI compound, a group IV element, a group IV compound, and a combination thereof.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-VI compound may include a binary compound such as In₂S₃ and/or In₂Se₃; a ternary compound such as InGaS₃ and/or InGaSe₃; or any combination thereof.

The group I-III-VI compound may be selected from a ternary compound such as AgInS, AgInS₂, CuInS, CuInS₂, AgGaS₂, CuGaS₂ CuGaO₂, AgGaO₂, AgAlO₂ and/or a mixture thereof; and a quaternary compound such as AgInGaS₂ and/or CuInGaS₂.

The group III-V compound may be selected from the group consisting of: a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof. In one or more embodiments, the group III-V compound may further include a group II metal. For example, InZnP and/or the like may be selected as the group III-II-V compound.

The group IV-VI compound may be selected from the group consisting of: a binary compound selected from the group consisting of SnS, SnSe, SnTe, PbS, PbSe, PbTe and mixtures thereof; a ternary compound selected from the group consisting of SnSeS, SnSeTe, SnSTe, PbSeS, PbSeTe, PbSTe, SnPbS, SnPbSe, SnPbTe and mixtures thereof; and a quaternary compound selected from the group consisting of SnPbSSe, SnPbSeTe, SnPbSTe and mixtures thereof. The group IV element may be selected from the group consisting of Si, Ge, and mixtures thereof. The group IV compound may be a binary compound selected from the group consisting of SiC, SiGe, and mixtures thereof.

In this case, the binary compound, the ternary compound, and/or the quaternary compound may be present in the particle with a uniform concentration, or may be present in the same particle with partially different concentrations. In one or more embodiments, the quantum dot may have a core/shell structure in which one quantum dot surrounds (e.g., is around) another quantum dot. In the core/shell structure, the concentration of elements present in the shell may have a concentration gradient that decreases toward the core.

In some embodiments, the quantum dots QD1, QD2, and QD3 may have a core-shell structure including a core containing the above-described nanocrystal and a shell surrounding the core. The shell of the quantum dot QD1, QD2, and/or QD3 may serve as a protective layer for maintaining semiconductor characteristics by preventing or reducing chemical modification of the core and/or serve as a charging layer for imparting electrophoretic characteristics to the quantum dot. The shell may be a single layer or a plurality of layers. Examples of the shell of the quantum dot QD1, QD2, and/or QD3 may include a metal oxide, a non-metal oxide, a semiconductor compound, and combinations thereof.

For example, the metal oxide and the non-metal oxide may each independently include a binary compound such as SiO₂, Al2O₃, TiO₂, ZnO, MnO, Mn₂O₃, Mn₃O₄, CuO, FeO, Fe₂O₃, Fe₃O₄, CoO, Co₃O₄, and/or NiO; and/or a ternary compound such as MgAl₂O₄, CoFe₂O₄, NiFe₂O₄, and/or CoMn₂O₄, but one or more embodiments of the present disclosure are not limited thereto.

Additional examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but one or more embodiments of the present disclosure are not limited thereto.

The quantum dots QD1, QD2, and QD3 may have a full width of half maximum (FWHM) of an emission wavelength spectrum of about 45 nm or less, for example, about 40 nm or less, or about 30 nm or less, and in any of these ranges, the color purity and/or the color reproducibility may be improved. In addition, light emitted through these quantum dots QD1, QD2, and QD3 is emitted in all directions, so that wide viewing angle characteristics may be improved.

The shape of the quantum dot QD1, QD2, and/or QD3 is not particularly limited. For example, the quantum dos QD1, QD2, and/or QD3 may have a shape such as a spherical shape, a pyramidal shape, a multi-arm shape, and/or a cubic nanoparticle, a nanotube, a nanowire, a nanofiber, and/or a nanoplatelet particle.

The quantum dots QD1, QD2, and QD3 may control the color of emitted light according to the particle size, and accordingly, the quantum dots QD1, QD2, and QD3 may have various emission colors such as blue, red, and green. The quantum dots may emit light in a shorter wavelength range as the particle size of the quantum dots QD1, QD2, and QD3 is smaller. For example, in the quantum dots QD1, QD2, and QD3 having the same core, the particle size of the quantum dot that is to emit green light may be smaller than the particle size of the quantum dot that is to emit red light. In one or more embodiments, in the quantum dots QD1, QD2, and QD3 having the same core, the particle size of the quantum dot that is to emit blue light may be smaller than the particle size of the quantum dot that is to emit green light. However, one or more embodiments of the present disclosure are not limited thereto, and the particle size may be adjusted according to a shell forming material and a shell thickness even in the quantum dots QD1, QD2, and QD3 having the same core.

When the quantum dots QD1, QD2, and QD3 have various emission colors such as blue, red, and green, the quantum dots QD1, QD2, and QD3 having different emission colors may have different core materials.

In one or more embodiments, the first to third quantum dots QD1, QD2, and QD3 may have different diameters. For example, the first quantum dot QD1 used in the first light-emitting element ED-1 emitting light in a relatively short wavelength range may have a relatively smaller average diameter than the second quantum dot QD2 of the second light-emitting element ED-2 and the third quantum dot QD3 of the third light-emitting element ED-3 which are to emit light in a relatively long wavelength range.

In this specification, the average diameter corresponds to the arithmetic average of the diameters of a plurality of quantum dot particles. The diameter of the quantum dot particle may be an average value of the width of the quantum dot particles in a cross section.

The relationship regarding the average diameters of the first to third quantum dots QD1, QD2, and QD3 is not limited to the above limitation. For example, although FIG. 5 illustrates that the sizes of the quantum dots QD1, QD2, and QD3 are illustrated to be similar to each other, the sizes of the first to third quantum dots QD1, QD2, and QD3 included in the light-emitting elements ED-1, ED-2, and ED-3 may be different from each other. In one or more embodiments, the average diameters of two quantum dots selected from among the first to third quantum dots QD1, QD2, and QD3 may be similar and the average diameter of the rest may be different.

In the light-emitting elements ED-1, ED-2, and ED-3 according to one or more embodiments, the light-emitting layers EML-B, EML-G, and EML-R may include a host and a dopant. In one or more embodiments, the light-emitting layers EML-B, EML-G, and EML-R may include the quantum dots QD1, QD2, and QD3 as a dopant material. In one or more embodiments, the light-emitting layers EML-B, EML-G, and EML-R may further include a host material. In the light-emitting elements ED-1, ED-2, and ED-3 according to one or more embodiments, the light-emitting layers EML-B, EML-G, and EML-R may emit fluorescence. For example, the quantum dots QD1, QD2, and QD3 may be used as a fluorescent dopant material.

In one or more embodiments, each of the first to third quantum dots QD1, QD2, and QD3 may be a quantum dot to which a ligand and/or the like for improving dispersibility is bonded to the surface thereof.

In the display device DD according to one or more embodiments illustrated in FIGS. 4 and 5, the light-emitting regions PXA-B, PXA-G, and PXA-R may respectively have different areas. In this case, the area may be an area when the light-emitting region is viewed on a plane defined by the first direction DR1 and the second direction DR2 (e.g., in plan view).

The light-emitting regions PXA-B, PXA-G, and PXA-R may have different areas depending on the colors of light emitted from the light-emitting layers EML-B, EML-G, and EML-R of the light-emitting elements ED-1, ED-2, and ED-3. For example, referring to FIGS. 4 and 5, in the display device DD according to one or more embodiments, the blue light-emitting region PXA-B corresponding to the first light-emitting element ED-1 that is to emit blue light may have the largest area, and the green light-emitting region corresponding to the second light-emitting element ED-2 that is to generate green light may have the smallest area. However, one or more embodiments of the present disclosure are not limited thereto, and the light-emitting regions PXA-B, PXA-G, and PXA-R may emit light of a color other than blue light, green light, and/or red light, or the light-emitting regions PXA-B, PXA-G, and PXA-R may have the same area, or the light-emitting regions PXA-B, PXA-G, and PXA-R may be provided at a different area ratio than that illustrated in FIG. 4.

The light-emitting regions PXA-B, PXA-G, and PXA-R may be regions respectively divided by the pixel defining layers PDL. The peripheral regions NPXA may be located between the adjacent light-emitting regions PXA-B, PXA-G, and PXA-R and correspond to the pixel defining layers PDL. Meanwhile, in the present specification, the respective light-emitting regions PXA-B, PXA-G, and PXA-R may correspond to pixels. The pixel defining layers PDL may divide the light-emitting elements ED-1, ED-2, and ED-3. The light-emitting layers EML-B, EML-G, and EML-R of the light-emitting elements ED-1, ED-2, and ED-3 may be divided by being disposed in the openings OH defined by the pixel defining layers PDL. In one or more embodiments, the first light-emitting layer EML-B of the first light-emitting element ED-1 may be disposed in the first opening OH1, the second light-emitting layer EML-G of the second light-emitting element ED-2 may be disposed in the second opening OH2, and the third light-emitting layer EML-R of the third light-emitting element ED-3 may be disposed in the third opening OH3.

Each pixel defining layer PDL may be formed of a polymer resin. For example, the pixel defining layer PDL may be formed of a polyacrylate-based resin and/or a polyimide-based resin. In one or more embodiments, the pixel defining layer PDL may be formed by further including an inorganic material in addition to the polymer resin. For example, the pixel defining layer PDL may be formed by including a light absorbing material, or may be formed by including a black pigment or a black dye. The pixel defining layer PDL formed by including a black pigment or black dye may form a black pixel defining layer. Carbon black and/or the like may be used as a black pigment or a black dye in formation of the pixel defining layer PDL, but one or more embodiments of the present disclosure are not limited thereto.

In one or more embodiments, the pixel defining layers PDL may be formed of an inorganic material. For example, the pixel defining layers PDL may be formed by including silicon nitride (SiNₓ), silicon oxide (SiOₓ), silicon oxynitride (SiOₓN_{y}), silicon nitride oxide (SiNₓO_{y}), and/or the like. The pixel defining layers PDL may define the light-emitting regions PXA-B, PXA-G, and PXA-R. The light-emitting regions PXA-B, PXA-G, and PXA-R and the peripheral region NPXA may be divided by the pixel defining layers PDL.

The light-emitting elements ED-1, ED-2, and ED-3 may respectively include first electrodes EL1, hole transport regions HTR-1, HTR-2, and HTR-3 disposed on the first electrode EL1, light-emitting layers EML-B, EML-G, and EML-R disposed on the hole transport regions HTR-1, HTR-2, and HTR-3, electron transport regions ETR-1, ETR-2, and ETR-3 disposed on the light-emitting layers EML-B, EML-G, and EML-R, and second electrodes EL2 disposed on the electron transport regions ETR-1, ETR-2, and ETR-3.

The hole transport regions HTR-1, HTR-2, and HTR-3 and the electron transport regions ETR-1, ETR-2, and ETR-3 respectively included in the light-emitting elements ED-1, ED-2, and ED-3 may be divided by being disposed in the corresponding openings OH1, OH2, and OH3 defined in the pixel defining layer PDL.

For example, a first hole transport region HTR-1 and a first electron transport region ETR-1 included in the first light-emitting element ED-1 may be disposed adjacent to the first light-emitting layer EML-B, and may be patterned and disposed in the first opening OH1 in which the first light-emitting layer EML-B is disposed. A second hole transport region HTR-2 and a second electron transport region ETR-2 included in the second light-emitting element ED-2 may be disposed adjacent to the second light-emitting layer EML-G, and may be patterned and disposed in the second opening OH2 in which the second light-emitting layer EML-G is disposed. A third hole transport region HTR-3 and a third electron transport region ETR-3 included in the third light-emitting element ED-3 may be disposed adjacent to the third light-emitting layer EML-R, and may be patterned and disposed in the third opening OH3 in which the third light-emitting layer EML-R is disposed. However, one or more embodiments of the present disclosure are not limited thereto, and any of the hole transport regions HTR-1, HTR-2, and HTR-3 and the electron transport regions ETR-1, ETR-2, and ETR-3 may be provided as common layers commonly (e.g., integrally) disposed in the pixel regions PXA-B, PXA-G, and PXA-R and the peripheral region NPXA.

In one or more embodiments, the hole transport regions HTR-1, HTR-2, and HTR-3 and the electron transport regions ETR-1, ETR-2, and ETR-3 may be respectively provided in the openings OH1, OH2, and OH3 defined in the pixel defining layers PDL through a printing process.

The encapsulation layer TFE may cover the light-emitting elements ED-1, ED-2, and ED-3. The encapsulation layer TFE may seal the display element layer DP-EL. The encapsulation layer TFE may be a thin-film encapsulation layer. The encapsulation layer TFE may be a single layer or a stack of a plurality of layers. The encapsulation layer TFE includes at least one insulating layer. The encapsulation layer TFE according to one or more embodiments may include at least one inorganic film (hereinafter, an inorganic encapsulation film). In one or more embodiments, the encapsulation layer TFE may include at least one organic film (hereinafter, an organic encapsulation film) and at least one inorganic encapsulation film.

The inorganic encapsulation film protects the display element layer DP-EL from moisture/oxygen, and the organic encapsulation film protects the display device layer DP-EL from foreign substances such as dust particles. The inorganic encapsulation film may include a silicon nitride, a silicon oxy nitride, a silicon oxide, a titanium oxide, an aluminum oxide, and/or the like, but is not particularly limited thereto. The organic encapsulation film may include an acrylic-based compound, an epoxy-based compound, and/or the like. The organic encapsulation film may include a photopolymerizable organic material but is not particularly limited.

The encapsulation layer TFE may be disposed on the second electrode EL2, and fill the openings OH1, OH2 and OH3.

In the display device DD according to one or more embodiments illustrated in FIG. 5, the thicknesses of the light-emitting layers EML-B, EML-G, and EML-R of the first to third light-emitting elements ED-1, ED-2, and ED-3 are all the same (or substantially the same). However, one or more embodiments of the present disclosure are not limited thereto. For example, in one or more embodiments, the thicknesses of the light-emitting layers EML-B, EML-G, and EML-R of the first to third light-emitting elements ED-1, ED-2, and ED-3 may be different from each other. In one or more embodiments, the hole transport regions HTR-1, HTR-2, and HTR-3 and the electron transport regions ETR-1, ETR-2, and ETR-3 of the light-emitting elements ED-1, ED-2, and ED-3 may also have different thicknesses.

Referring to FIG. 4, the blue light-emitting regions PXA-B and the red light-emitting regions PXA-R may be alternately arranged with each other along the first direction DR1 to form a first group PXG1. The green light-emitting regions PXA-G may be arranged with each other along the first direction DR1 to form a second group PXG 2.

The first group PXG1 may be disposed to be spaced apart from the second group PXG2 in the second direction DR2. Each of the first group PXG1 and the second group PXG2 may be provided in plural. The first groups PXG1 and the second groups PXG2 may be alternately arranged with each other along the second direction DR2.

One green light-emitting region PXA-G may be disposed to be spaced apart from one blue light-emitting region PXA-B and/or one red light-emitting region PXA-R in a fourth direction DR4. The fourth direction DR4 may be a direction (e.g., a diagonal direction) between the first direction DR1 and the second direction DR2.

The arrangement structure of the light-emitting regions PXA-B, PXA-G, and PXA-R illustrated in FIG. 4 may be called a PenTile®/PENTILE® structure (PENTILE® is a registered trademark owned by Samsung Display Co., Ltd.). However, the arrangement structure of the light-emitting regions PXA-B, PXA-G, and PXA-R in the display device DD according to one or more embodiments of the present disclosure is not limited to the arrangement structure illustrated in FIG. 4. For example, in one or more embodiments, the light-emitting regions PXA-B, PXA-G, and PXA-R may have a stripe structure in which the blue light-emitting region PXA-B, the green light-emitting region PXA-G, and the red light-emitting region PXA-R are alternately arranged in sequence with each other along the first direction DR1.

Referring to FIGS. 3 and 5, the display device DD according to one or more embodiments may further include an optical member PP. The optical member PP may block or reduce external light provided from the outside of the display device DD to the display panel DP. The optical member PP may block or reduce a part of the external light. The optical member PP may have an anti-reflection function to minimize or reduce reflection by external light.

In one or more embodiments illustrated in FIG. 5, the optical member PP may include a base layer BL and a color filter layer CFL. The display device DD according to one or more embodiments may further include a color filter layer CFL disposed on the light-emitting elements ED-1, ED-2, and ED-3 of the display panel DP.

The base layer BL may be a member that provides a base surface on which the color filter layer CFL and/or the like is disposed. The base layer BL may be a glass substrate, a metal substrate, a plastic substrate, and/or the like. However, one or more embodiments of the present disclosure are not limited thereto, and the base layer BL may be an inorganic layer, an organic layer, or a composite material layer.

The color filter layer CFL may include a light blocking portion BM and a color filter portion CF. The color filter portion CF may include a plurality of filters CF-B, CF-G, and CF-R. For example, the color filter layer CFL may include a first filter CF-B that is to transmit first light, a second filter CF-G that is to transmit second light, and a third filter CF-R that is to transmit third light. For example, the first filter CF-B may be a blue filter, the second filter CF-G may be a green filter, and the third filter CF-R may be a red filter.

Each of the filters CF-B, CF-G, and CF-R may contain a polymer photosensitive resin and a pigment or dye. The first filter CF-B may contain a blue pigment or dye, the second filter CF-G may contain a green pigment or dye, and the third filter CF-R may contain a red pigment or dye.

However, one or more embodiments of the present disclosure are not limited thereto, and the first filter CF-B may not contain a pigment or dye. The first filter CF-B may contain a polymer photosensitive resin and may not contain a pigment or dye. The first filter CF-B may be transparent. The first filter CF-B may be formed of a transparent photosensitive resin.

The light blocking portion BM may be a black matrix. The light blocking portion BM may be formed by including an inorganic light blocking material or an organic light blocking material containing a black pigment or black dye. The light blocking portion BM may prevent or reduce light leakage phenomenon and demarcate boundaries between adjacent filters CF-B, CF-G, and CF-R.

The color filter layer CFL may further include a buffer layer BFL. For example, the buffer layer BFL may be a protective layer that protects the filters CF-B, CF-G, and CF-R. The buffer layer BFL may be an inorganic material layer including at least one of silicon nitride, silicon oxide, or silicon oxynitride. The buffer layer BFL may be formed of a single layer or a plurality of layers.

In one or more embodiments illustrated in FIG. 5, the first filter CF-B of the color filter layer CFL is illustrated to overlap the second filter CF-G and the third filter CF-R, but one or more embodiments of the present disclosure are not limited thereto. For example, the first to third filters CF-B, CF-G, and CF-R may be divided by the light blocking portion BM and may not overlap with each other. In one or more embodiments, the first to third filters CF-B, CF-G, and CF-R may be disposed to respectively correspond to the blue light-emitting region PXA-B, the green light-emitting region PXA-G, and the red light-emitting region PXA-R. In one or more embodiments, the color filter layer CFL may be omitted in the display device DD.

In one or more embodiments, the display device DD may include, as the optical member PP, a polarizing layer in place of the color filter layer CFL. The polarizing layer may block or reduce external light provided from the outside to the display panel DP. The polarizing layer may block or reduce some of the external light.

In one or more embodiments, the polarizing layer may reduce reflected light obtained by reflecting external light by the display panel DP. For example, the polarizing layer may function to block or reduce reflected light when light provided from the outside of the display device DD enters the display panel DP and exits again. The polarizing layer may be a circular polarizer having an antireflection function, or the polarizing layer may include a linear polarizer and a λ/4 phase retarder. In one or more embodiments, the polarizing layer may be disposed (e.g., positioned) on and exposed on the base layer BL, or the polarizing layer may be disposed (e.g., positioned) below the base layer BL.

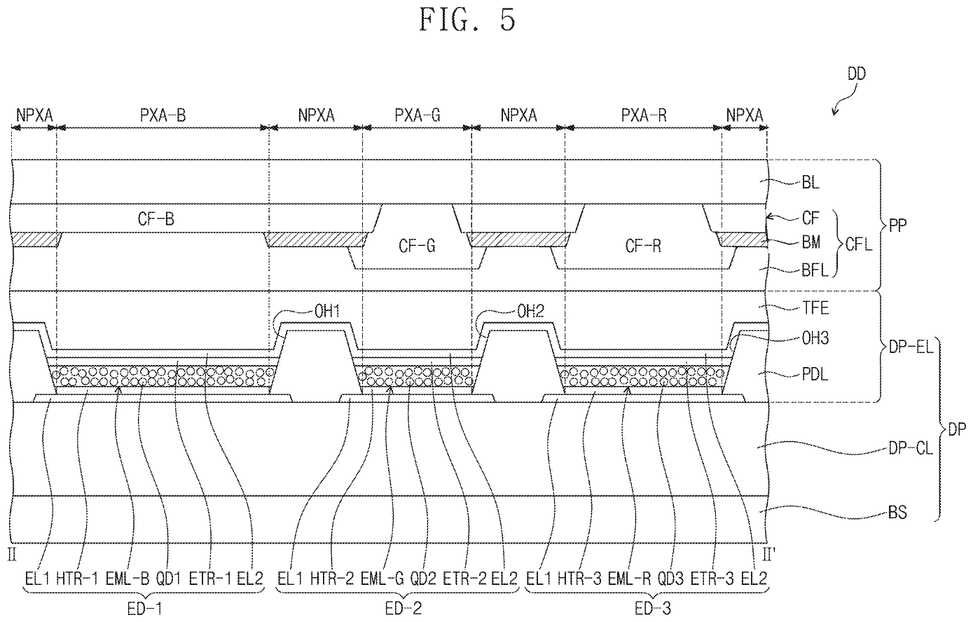

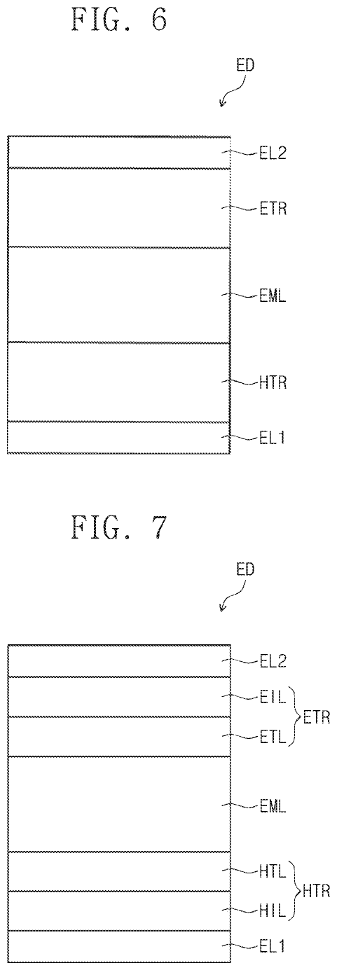

FIGS. 6 to 9 are cross-sectional views of a light-emitting element according to one or more embodiments of the present disclosure.

Referring to FIG. 6, the light-emitting element ED may include the first electrode EL1, the hole transport region HTR, the light-emitting layer EML, the electron transport region ETR, and the second electrode EL2 which are stacked in sequence.

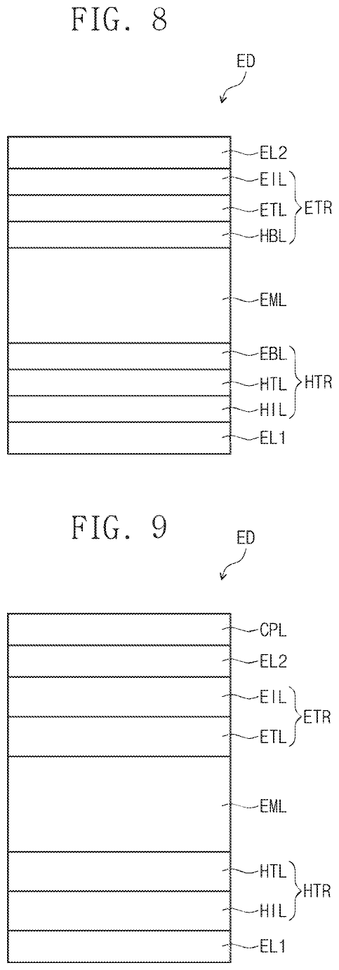

FIG. 7 is a cross-sectional view of a light-emitting element ED according to one or more embodiments in which the hole transport region HTR includes a hole injection layer HIL and a hole transport layer HTL, and the electron transport region ETR includes an electron injection layer EIL and an electron transport layer ETL, as compared to FIG. 6. FIG. 8 is a cross-sectional view of a light-emitting element ED according to one or more embodiments in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL, as compared to FIG. 6. Compared to FIG. 6, FIG. 9 is a cross-sectional view of a light-emitting element ED, according to one or more embodiments, including a capping layer CPL disposed on the second electrode EL2

In the light-emitting element ED according to one or more embodiments, the first electrode EL1 has conductivity. The first electrode EL1 may be formed of a metal alloy or any suitable conductive compound. The first electrode EL1 may be an anode. The first electrode EL1 may be a pixel electrode.

In the light-emitting element ED according to the embodiments, the first electrode EL1 may be a reflective electrode. However, one or more embodiments of the present disclosure are not limited thereto. For example, the first electrode EL1 may be a transmissive electrode, a transflective electrode, and/or the like. When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (e.g., a mixture of Ag and Mg). In one or more other embodiments, the first electrode EL1 may have a multilayer structure including a reflective film or a semi-transmissive film formed of any of the above-described materials, and a transparent conductive film formed of indium tin oxide (ITO), indium zinc oxide (IZO), zinc oxide (ZnO), indium tin zinc oxide (ITZO), and/or the like. For example, the first electrode EL1 may be a multilayer metal film, and may have a structure in which metal films of ITO/Ag/ITO are stacked.

The hole transport region HTR is provided on the first electrode EL1. The hole transport region HTR may include a hole injection layer HIL and a hole transport layer HTL. In one or more embodiments, the hole transport region HTR may further include at least one of a hole buffer layer or an electron blocking layer EBL, in addition to the hole injection layer HIL and the hole transport layer HTL. The hole buffer layer may increase a luminous efficiency by compensating for a resonance distance according to the wavelength of light emitted from the light-emitting layer EML. Any material that may be included in the hole transport region HTR may be used as a material included in the hole buffer layer. The electron blocking layer EBL is a layer that prevents or reduces the injection of electrons from the electron transport region ETR to the hole transport region HTR.

The hole transport region HTR may have a single layer formed of a single material, a single layer formed of a plurality of different materials, or a multilayer structure having a plurality of layers formed of a plurality of different materials. For example, the hole transport region HTR may have a structure of single layers formed of a plurality of different materials, or may have a structure such as a hole injection layer HIL/hole transport layer HTL, a hole injection layer HIL/hole transport layer HTL/hole buffer layer, a hole injection layer HIL/hole buffer layer, a hole transport layer HTL/hole buffer layer, or a hole injection layer HIL/hole transport layer HTL/electron blocking layer EBL, which are sequentially stacked from the first electrode EL1, but one or more embodiments of the present disclosure are not limited thereto.

The hole transport region HTR may be formed using one or more suitable methods such as a vacuum evaporation method, a spin coating method, a cast method, a LB method (Langmuir-Blodgett), an inkjet printing method, a laser printing method, and/or a laser induced thermal imaging (LITI).

The hole injection layer HIL may include a phthalocyanine compound (such as copper phthalocyanine), N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris{N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPD), polyetherketone containing triphenylamine (TPAPEK), 4-Isopropyl-4′-methyldiphenyliodonium [tetrakis(pentafluorophenyl)borate], dipyrazino[2,3-f: 2′,3′-h] quinoxaline-2,3,6,7,10,11-hexacarbonitrile (HAT-CN), and/or the like.

The hole transport layer HTL may include any suitable material. For example, the hole transport layer HTL may further include carbazole-based derivative (such as N-phenylcarbazole and/or polyvinylcarbazole), fluorine-based derivatives, triphenylamine-based derivatives (such as N,N′-bis(3-methylphenyl)-N,N′-diphenyl-[1,1-biphenyl]-4,4′-diamine (TPD), and/or 4,4′,4″-tris(N-carbazolyl)triphenylamine (TCTA)), N,N′-di(naphthalene-l-yl)-N,N′-diphenyl-benzidine (NPD), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

The thickness of the hole transport region HTR may be about 5 nm to about 1,500 nm, for example, about 10 nm to about 500 nm. The thickness of the hole injection layer HIL may be, for example, about 3 nm to about 100 nm, and the thickness of the hole transport layer HTL may be about 3 nm to about 100 nm. For example, the thickness of the electron blocking layer EBL may be about 1 nm to about 100 nm. When the thicknesses of the hole transport region HTR, the hole injection layer HIL, the hole transport layer HTL, and the electron blocking layer EBL satisfy their respective above-described ranges, satisfactory (or suitable) electron injection characteristics may be obtained without a substantial increase in driving voltage.

The light-emitting layer EML is provided on the hole transport region HTR. For example, the light-emitting layer EML may have a thickness of about 10 nm to about 100 nm, or about 10 nm to about 30 nm. The light-emitting layer EML may have a single layer formed of a single material, a single layer formed of a plurality of different materials, or a multilayer structure having a plurality of layers formed of a plurality of different materials. In the light-emitting element ED according to one or more embodiments, the light-emitting layer EML may include the quantum dot QD1, QD2, and/or QD3 (see FIG. 5).

The light-emitting layer EML may be formed using one or more suitable methods such as a vacuum evaporation method, a spin coating method, a cast method, a LB method (Langmuir-Blodgett), an inkjet printing method, a laser printing method, and/or a laser induced thermal imaging (LITI). In one or more embodiments, the light-emitting layer EML may be formed by providing a quantum dot composition including the quantum dot QD1, QD2, and/or QD3 (see FIG. 5) using an inkjet printing method.

In the light-emitting element ED according to one or more embodiments, the electron transport region ETR is provided on the light-emitting layer EML. The electron transport region ETR may include at least one of a hole blocking layer HBL, an electron transport layer ETL, or an electron injection layer EIL, but one or more embodiments of the present disclosure are not limited thereto.

The electron transport region ETR may include: a metal oxide; and an acid and a conjugate base of the acid which are generated by decomposition of and a photoacid generator. A more detailed description of the photoacid generator will be provided herein below.

In one or more embodiments, the metal oxide may include at least any one selected from among silicon, aluminum, zinc, indium, gallium, yttrium, germanium, scandium, titanium, tantalum, hafnium, zirconium, cerium, molybdenum, nickel, chromium, iron, niobium, tungsten, tin, copper, and mixtures thereof, but one or more embodiments of the present disclosure are not limited thereto.

In one or more embodiments, the metal oxide may include a zinc oxide. The type (or kind) of zinc oxide is not particularly limited, but may be, for example, ZnO, ZnMgO, or a combination thereof, and may be doped with Li and Y in addition to Mg. In one or more embodiments, the metal oxide may include TiO₂, SiO₂, SnO₂, WO₃, Ta₂O₃, BaTiO₃, BaZrO₃, ZrO₂, HfO₂, Al₂O₃, Y₂O₃, ZrSiO₄, and/or the like as inorganic materials in addition to the zinc oxide, but one or more embodiments of the present disclosure are not limited thereto.

The electron transport region ETR may be formed of an electron transport composition according to one or more embodiments of the present disclosure, which will be described herein below. For example, the electron transport region ETR may be formed of a composition including the metal oxide and the photoacid generator.

In the case of forming an electron transport region using a metal oxide in a comparable light-emitting element, a positive aging method that introduces a resin layer capable of supplying an acid onto the electron transport region was used to improve luminous efficiency and lifespan characteristics. However, this method results in a haze phenomenon caused by the resin layer and thus has limitations such as low transmittance when applied to a front emitting structure. Moreover, this method has a limitation in that process efficiency is lowered due to an increase in process time and manufacturing cost because a series of processes for resin application are to be added.

In the present disclosure, the surface characteristics of the metal oxide may be changed by introducing a photoacid generator into an electron transport composition containing the metal oxide, and accordingly, the electrical and optical characteristics of the light-emitting element may be adjusted, thereby improving the luminous efficiency and lifespan of the display device. In addition, unlike comparable methods of additionally introducing the resin layer on the electron transport region, the photoacid generator is directly introduced into the electron transport composition, so that the haze phenomenon caused by the resin is suppressed or substantially reduced. Thus, the present disclosure may be applied to both front and bottom light-emitting structures, and also may reduce manufacturing cost and process time, thereby improving the reliability and productivity of the display device.

The electron transport region ETR may have a single layer formed of a single material, a single layer formed of a plurality of different materials, or a multilayer structure having a plurality of layers formed of a plurality of different materials.

For example, the electron transport region ETR may have a single-layer structure of the electron injection layer EIL or the electron transport layer ETL, or may have a single-layer structure formed of an electron injection material and an electron transport material. In one or more embodiments, the electron transport region ETR may have a single layer formed of a plurality of different materials, or may have a structure such as an electron transport layer ETL/electron injection layer EIL, or a hole blocking layer HBL/electron transport layer ETL/electron injection layer EIL, which are sequentially stacked from the light-emitting layer EML, but one or more embodiments of the present disclosure are not limited thereto. The thickness of the electron transport region ETR may be, for example, about 20 nm to about 150 nm.

When the electron transport region ETR has a multilayer structure having a plurality of layers, at least one of the plurality of layers may be formed of an electron transport composition according to one or more embodiments of the present disclosure. For example, the electron transport region ETR may include the electron transport layer ETL disposed on the light-emitting layer EML, and the electron injection layer EIL disposed on the electron transport layer ETL, and the electron transport layer ETL may be formed of the electron transport composition according to one or more embodiments.

The electron transport layer ETR may be formed using one or more suitable methods such as a vacuum evaporation method, a spin coating method, a cast method, a LB method (Langmuir-Blodgett), an inkjet printing method, a laser printing method, and/or a laser induced thermal imaging (LITI). In one or more embodiments, the electron transport region ETR may be formed using the inkjet printing method.

In one or more embodiments, the electron transport region ETR may include any suitable inorganic material or any suitable organic material.

When the electron transport region ETR includes the electron transport layer ETL, the electron transport region ETR may include an anthracene-based compound. However, one or more embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, bis[2-(diphenylphosphino)phenyl]ether oxide (DPEPO), 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq₂), 9,10-di(naphthalene-2-yl)anthracene (ADN), or a mixture thereof. The thickness of the electron transport layer ETL may be about 10 nm to about 100 nm, for example, about 15 nm to about 50 nm. When the thickness of the electron transport layer ETL satisfies any of the above-described ranges, satisfactory (or suitable) electron transport characteristics may be obtained without a substantial increase in driving voltage.

When the electron transport region ETR includes the electron injection layer EIL, the electron transport region ETR may include a metal halide (such as LiF, NaCl, CsF, RbCl, and/or RbI), a lanthanum group metal (such as Yb), a metal oxide (such as Li₂O and/or BaO), and/or lithium quinolate (LiQ), but one or more embodiments of the present disclosure are not limited thereto. In one or more embodiments, the electron injection layer EIL may be formed of a material in which an electron transport material and an insulating organometallic salt are mixed. For example, the organometallic salt may include metal acetate, metal benzoate, metal acetoacetate, metal acetylacetonate, and/or metal stearate. The electron injection layer EIL may have a thickness of about 0.1 nm to about 10 nm, or about 0.3 nm to about 9 nm. When the thickness of the electron injection layer EIL satisfies any of the above-described ranges, satisfactory (or suitable) electron transport characteristics may be obtained without a substantial increase in driving voltage.

As described above, the electron transport region ETR may include a hole blocking layer HBL. The hole blocking layer HBL may include, for example, at least one of 2,9-dimethyl-4,7-diphenyl-1,10-phenanthroline (BCP) or 4,7-diphenyl-1,10-phenanthroline (Bphen), but one or more embodiments of the present disclosure are not limited thereto.

The second electrode EL2 is provided on the electron transport region ETR. The second electrode EL2 may be a common electrode and/or a negative electrode. The second electrode EL2 may be a transmissive electrode, a transflective electrode, or a reflective electrode. When the second electrode EL2 is the transmissive electrode, the second electrode EL2 may include a transparent metal oxide such as indium tin oxide (ITO), indium zinc oxide (IZO), zinc oxide (ZnO), and/or indium tin zinc oxide (ITZO).

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (e.g., a mixture of Ag and Mg). In one or more embodiments, the second electrode EL2 may have a multilayer structure including a reflective film or a semi-transmissive film formed of any of the above-described materials and a transparent conductive film formed of indium tin oxide (ITO), indium zinc oxide (IZO), zinc oxide (ZnO), indium tin zinc oxide (ITZO), and/or the like.

In one or more embodiments, the second electrode EL2 may be connected (e.g., electrically and/or physically coupled) to an auxiliary electrode. When the second electrode EL2 is connected to the auxiliary electrode, the resistance of the second electrode EL2 may be reduced.

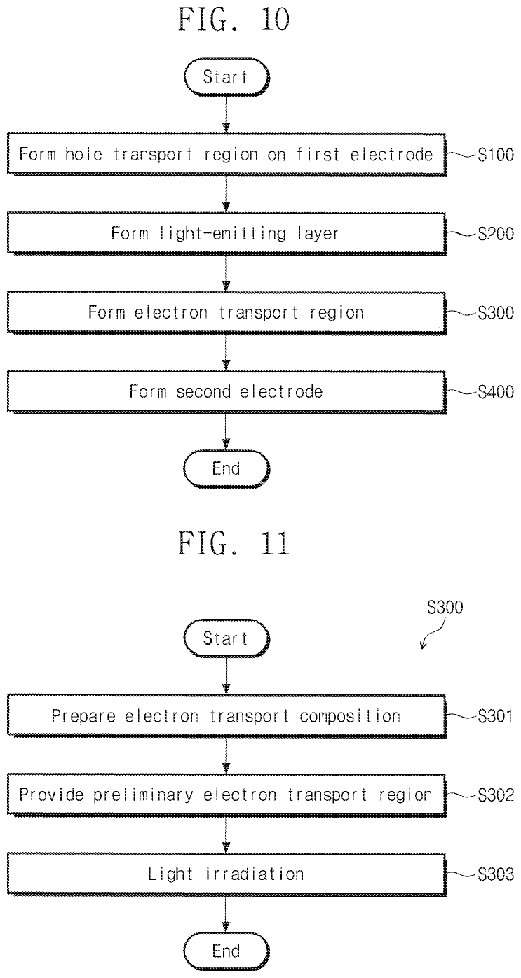

FIG. 10 is a flowchart illustrating a method of manufacturing a light-emitting element according to one or more embodiments. FIG. 11 is a flowchart in which the act of forming of an electron transport region (S300) according to one or more embodiments is subdivided into several acts.

Referring to FIG. 10, a method of manufacturing a light-emitting element according to one or more embodiments includes forming a hole transport region on a first electrode (S100), forming a light-emitting layer on the hole transport region (S200), forming an electron transport region on the light-emitting layer (S300), and forming a second electrode on the electron transport region (S400).

Referring to FIG. 11, the forming of the electron transport region on the light-emitting layer (S300) includes preparing an electron transport composition (S301), providing a preliminary electron transport region (S302), and irradiating the preliminary electron transport region with light (S303).

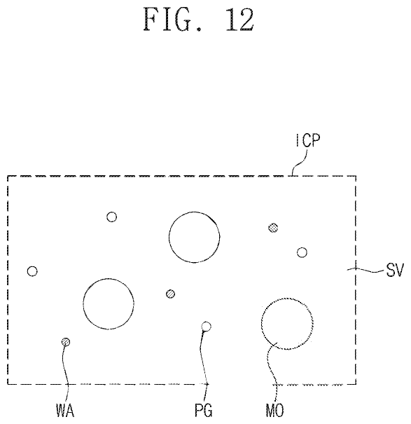

FIG. 12 is a diagram schematically illustrating an electron transport composition according to one or more embodiments. An electron transport composition ICP according to one or more embodiments of the present disclosure may be a material forming the electron transport region of the light-emitting element. However, one or more embodiments of the present disclosure are not limited thereto, and the electron transport composition ICP according to one or more embodiments may be a material that forms any one of the functional layers included in the hole transport region or the light-emitting layer of the light-emitting element.

Referring to FIG. 12, the electron transport composition ICP according to one or more embodiments includes a metal oxide MO and a photoacid generator PG. The shape of the metal oxide MO according to one or more embodiments is not particularly limited and may be any suitable shape. For example, the metal oxide MO may have a shape such as a spherical shape, a pyramidal shape, a multi-arm shape, a cubic shape, a nanoparticle (e.g., a cubic nanoparticle), a nanotube, a nanowire, a nanofiber, and/or a nanoplatelet particle.

The term “substituted or unsubstituted” in the present specification may mean a group that is unsubstituted or that is substituted with at least one substituent selected from the group consisting of a deuterium atom, a halogen atom, a cyano group, a nitro group, an amino group, a silyl group, a oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the substituents exemplified above may be substituted or unsubstituted. For example, the biphenyl group may be interpreted as an aryl group, and may also be interpreted as a phenyl group substituted with a phenyl group.

In the present specification, the term “bonded to an adjacent group to form a ring” may mean being bonded to an adjacent group to form a substituted or unsubstituted hydrocarbon ring or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may each independently be monocyclic or polycyclic. In addition, a ring formed by mutually bonding (e.g., a fused ring) may be connected to another ring to form a spiro structure.

In the present specification, the term “adjacent group” may refer to a pair of substituent groups where the first substituent is connected to an atom which is directly connected to another atom substituted with the second substituent; a pair of substituent groups connected to the same atom; or a pair of substituent groups where the first substituent is sterically positioned at the nearest position to the second substituent. For example, two methyl groups in 1,2-dimethylbenzene may be interpreted as mutually “adjacent groups”, and two ethyl groups in 1,1-diethylcyclopentane may be interpreted as mutually “adjacent groups.” In addition, two methyl groups in 4,5-dimethylphenanthrene may be interpreted as mutually “adjacent groups.”.

In the present specification, examples of the halogen atom may include a fluorine atom, a chlorine atom, a bromine atom, and an iodine atom.

In the present specification, the alkyl group may be straight, branched or cyclic. The number of carbon atoms in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, an 2-ethylbutyl group, a 3, 3-dimethylbutyl group, an n-pentyl group, an i-pentyl group, a neopentyl group, a t-pentyl group, a cyclopentyl group, a 1-methylpentyl group, a 3-methylpentyl group, an 2-ethylpentyl group, a 4-methyl-2-pentyl group, an n-hexyl group, a 1-methylhexyl group, an 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, an 2-ethylheptyl group, a 2-butylheptyl group, an n-octyl group, a t-octyl group, an 2-ethyloctyl group, a 2-butyloctyl group, an 2-hexyloctyl group, a 3,7-dimethyloctyl group, a cyclooctyl group, an n-nonyl group, an n-decyl group, an adamantyl group, an 2-ethyldecyl group, a 2-butyldecyl group, a 2-hexyldecyl group, an 2-octyldecyl group, an n-undecyl group, an n-dodecyl group, an 2-ethyldodecyl group, a 2-butyldodecyl group, an 2-hexyldodecyl group, an 2-octyldodecyl group, an n-tridecyl group, an n-tetradecyl group, an n-pentadecyl group, an n-hexadecyl group, an 2-ethylhexadecyl group, a 2-butylhexadecyl group, an 2-hexylhexadecyl group, an 2-octylhexadecyl group, an n-heptadecyl group, an n-octadecyl group, an n-nonadecyl group, an n-icosyl group, an 2-ethylicosyl group, a 2-butylicosyl group, an 2-hexylicosyl group, an 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like, but one or more embodiments of the present disclosure are not limited thereto.

In the present specification, the aryl group means any functional group or substituent derived from an aromatic hydrocarbon ring. The aryl group may be a monocyclic aryl group or a polycyclic aryl group. The number of ring-forming carbon atoms in the aryl group may be about 6 to about 30, about 6 to about 20, or about 6 to about 15. Examples of the aryl group may include a phenyl group, a naphthyl group, a fluorenyl group, an anthracenyl group, a phenanthryl group, a biphenyl group, a terphenyl group, a quarterphenyl group, a quinquephenyl group, a sexiphenyl group, a triphenylenyl group, a pyrenyl group, a benzofluoranthenyl group, a chrysenyl group, and the like, but one or more embodiments of the present disclosure are not limited thereto.

In the present specification, the heteroaryl group may include, as a hetero atom, at least one of B, O, N, P, Si, or S. When the heteroaryl group includes two or more hetero atoms, the two or more hetero atoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, a imidazole group, a triazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxy group, a phthalazine group, a pyrido pyrimidine group, a pyrido pyrazine group, a pyrazino pyrazine group, an isoquinoline group, an indole group, a carbazole group, an N-aryl carbazole group, an N-heteroaryl carbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and the like, but one or more embodiments of the present disclosure are not limited thereto.

In the present specification, the number of carbon atoms in the sulfinyl group and the number of carbon atoms in the sulfonyl group are not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the present specification, the thio group may include an alkyl thio group and an aryl thio group. The thio group may mean that a sulfur atom is bonded to an alkyl group or an aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and the like, but one or more embodiments of the present disclosure are not limited thereto.

In the present specification, the oxy group may mean that an oxygen atom is bonded to an alkyl group or an aryl group defined above. The oxy group may include an alkoxy group and an aryl oxy group. The alkoxy group may be straight, branched or cyclic. The number of carbon atoms in the alkoxy group is not particularly limited, but may be, for example, 1 to 20 or 1 to 10. Examples of the oxy group may include, methoxy, ethoxy, n-propoxy, isopropoxy, butoxy, pentyloxy, hexyloxy, octyloxy, nonyloxy, decyloxy, benzyloxy, and the like, but one or more embodiments of the present disclosure are not limited thereto.

In the present specification, the alkenyl group may be straight or branched. The number of carbon atoms in the alkenyl group is not particularly limited, but is 2 to 30, 2 to 20, or 2 to 10. Examples of the alkenyl group may include a vinyl group, a 1-butenyl group, a 1-pentenyl group, a 1,3-butadienyl aryl group, a styrenyl group, and a styryl vinyl group, but one or more embodiments of the present disclosure are not limited thereto.

In the present specification, description and examples of the alkyl group in an alkylthio group, an alkylsulfoxy group, an alkylaryl group, an alkylamino group, an alkyl boron group, an alkyl silyl group, and an alkylamine group are the same as in the above-described alkyl group.

In the present specification, description and examples of the aryl group in an aryloxy group, an arylthio group, an arylsulfoxy group, an arylamino group, an aryl boron group, an aryl silyl group, and an arylamine group are the same as in the above-described aryl group.

In the present specification, the photoacid generator may mean a material that releases at least one acid when being irradiated with light such as visible light, ultraviolet light, and/or infrared light. Meanwhile, in the present specification, the term “acid” may mean a compound that provides a hydrogen ion (H⁺). The photoacid generator may be an ionic or non-ionic compound. Examples of the photoacid generator may include sulfonium-based, iodonium-based, phosphonium-based, diazonium-based, sulfonate-based, pyridinium-based, triazine-based, and imide-based compounds, but one or more embodiments of the present disclosure are not limited thereto. In addition, the photoacid generator may be used independently or may also be used in mixture of two or more types (e.g., compounds). In one or more embodiments, the photoacid generator may include compounds that generate acids when energy other than light irradiation (for example, heat) is applied thereto.

Referring again to FIG. 12, the electron transport composition ICP according to one or more embodiments contains the photoacid generator PG. When the photoacid generator PG is included in the electron transport composition ICP including the metal oxide MO, surface modification may occur in the metal oxide MO. For example, the acid generated from the photoacid generator PG may cause the surface modification of the metal oxide MO, which may lead to n-doping of the metal oxide MO, thereby ultimately increasing the current density in the element.

In one or more embodiments, the electron transport composition ICP may include, as the photoacid generator PG, at least one of a halogenated triazine-based compound or an oxime sulfonate-based compound.

In one or more embodiments, the photoacid generator PG may be represented by Formula 1 or Formula 2 below:

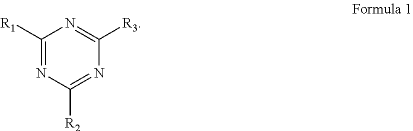

In Formula 1, R₁ to R₃ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. At least any one selected from among R₁ to R₃ is CX₃. X is a halogen atom. For example, the compound represented by Formula 1 may be 2-[2-(furan-2-yl)ethenyl]-4,6-bis(trichloromethyl)-s-triazine, 2-[2-(5-methylfuran-2-yl)ethenyl]-4,6-bis(trichloromethyl)-s-triazine, 2-(Methoxyphenyl)-4,6-bis(trichloromethyl)-s-triazine, 2-[2-(4-ethoxyphenyl)ethenyl]-4,6-bis(trichloromethyl)-s-triazine, 2-[2-(3,4-dimethoxyphenyl)ethenyl]-4,6-bis(trichloromethyl)-s-triazine, and/or the like. However, one or more embodiments of the present disclosure are not limited thereto.

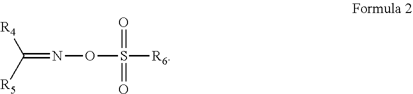

In Formula 2, R₄ and R₅ are each independently a hydrogen atom, a deuterium atom, a halogen atom, a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, or a substituted or unsubstituted heteroaryl group having 2 to 30 ring-forming carbon atoms. In one or more embodiments, R₄ and R₅ may each independently be bonded to an adjacent group to form a ring.

In Formula 2, R₆ is a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms. For example, the compound represented by Formula 2 may be 2-methyl-α-[2-[[(propylsulfonyl)oxy]imino]-3(2H)-thienylidene]benzeneacetonitrile, 2-methyl-α-[2-[[(4-methylphenylsulfonyl)oxy]imino]-3(2H)-thienylidene]benzeneacetonitrile, and/or the like, but one or more embodiments of the present disclosure are not limited thereto.

Hereinafter, the mechanism of action of the photoacid generator PG included in the electron transport composition of the present disclosure will be described in more detail. The photoacid generator PG according to one or more embodiments may be decomposed according to a mechanism such as Reaction Scheme 1 or Reaction Scheme 2 through light irradiation to generate an acid. Reaction Scheme 1 below illustrates the decomposition mechanism of the halogenated triazine-based compound represented by Formula 1 among the photoacid generator PG according to one or more embodiments of the present disclosure, and Reaction Scheme 2 below illustrates the decomposition mechanism of the oxime sulfonate-based compound represented by Formula 2 among the photoacid generator PG according to one or more embodiments of the present disclosure. However, these are merely examples, and one or more embodiments of the present disclosure are not limited thereto. In Reaction Scheme 1, the decomposition mechanism of the halogenated triazine-based compound including a trichloromethyl group as a substituent is illustrated as an example.

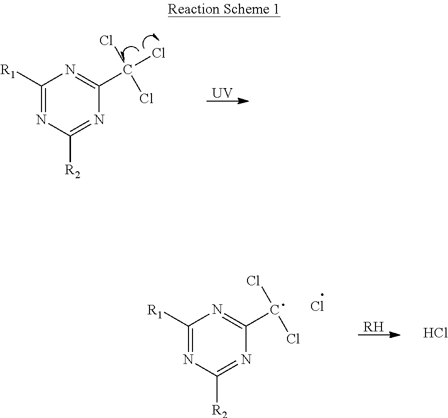

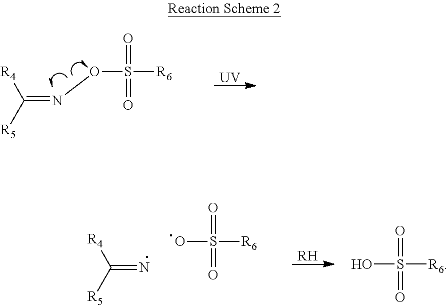

Referring to Reaction Scheme 1 and Reaction Scheme 2, when the photoacid generator is irradiated with light, the photoacid generator may be decomposed to form a radical. The radical may then be protonated by a proton material RH to form an acid. For example, the halogenated triazine-based compound may form a hydrogen halide such as HF, HCl, HBr, and/or HI, and the oxime sulfonate-based compound may form an acid molecule containing sulfonic acid groups. In Reaction Scheme 1 and Reaction Scheme 2, the proton material RH may be a compound that may provide at least one proton (hydrogen ion, H⁺). For example, the proton material RH may be a protic solvent and/or a polymer material that may provide protons.

The acid formed from the photoacid generator PG may release hydrogen ions (H⁺), and the hydrogen ions (H⁺) may diffuse to remove acetate groups adsorbed onto the surface of a metal oxide MO or adsorb onto oxygen atoms of the metal oxide MO. As a result, the surface of the metal oxide MO is modified to improve the optical and electrical characteristics of the light-emitting element.

In comparable devices, an electron transport composition including a metal oxide may include an acetate group derived from a metal oxide precursor. The acetate group may exist in a state of being adsorbed onto a metal atom of the metal oxide MO. When the acetate group is adsorbed onto the metal atom of the metal oxide MO, a Fermi level moves toward a valence band (VB), so that an energy difference between the Fermi level and the valence band may decrease. This causes the p-doping effect of the metal oxide in the electron transport region, resulting in a decrease in the current density of the element.

When the electron transport composition ICP according to one or more embodiments includes the photoacid generator PG, hydrogen ions (H⁺) formed from the photoacid generator PG may react with the acetate group adsorbed onto the metal oxide MO to remove the acetate group from the metal oxide MO. Accordingly, the Fermi level moves back toward a conduction band CB, so that the p-doping phenomenon may decrease and the current density may increase.

In addition, even when hydrogen ions (H⁺) formed from the photoacid generator PG are adsorbed onto oxygen atoms of the metal oxide MO, the Fermi level may move. For example, when hydrogen ions (H⁺) are adsorbed onto oxygen atoms of the metal oxide MO, the Fermi level moves toward the conduction band, and thus the energy difference between the Fermi level and the conduction band may decrease. As a result, the n-doping effect of the metal oxide may appear, and the current density of the element may increase ultimately. In this case, the degree by which the Fermi level is moved may be controlled according to the number of hydrogen ions (H⁺) adsorbed onto the oxygen atom, e.g., the concentration of hydrogen ions (H⁺).

Referring again to FIG. 12, the electron transport composition ICP may further include a weak acid WA. In one or more embodiments, the weak acid WA may have a pKa (acid dissociation constant) of at least about 4.75. When the pKa of the weak acid WA is less than about 4.75, the metal oxide MO and the acid react in the initial raw material state, which may cause an excess amount of the acetate group present in metal oxide MO precursor to be removed. Accordingly, the dispersion characteristics of the metal oxide MO in the electron transport composition ICP may be deteriorated, which may cause process degradation, uneven surface formation, etc.

In the present disclosure, the electron transport composition ICP that forms the electron transport region includes a photoacid generator PG or includes a photoacid generator PG and a weak acid WA having a pKa of about 4.75 or more, so that the acid may be slowly released. Therefore, the dispersion stability of the metal oxide may be improved, thereby making it is possible not only to form a uniform (or substantially uniform) thin film, but also to control the electrical and optical characteristics of the element through doping effects. Accordingly, when the electron transport region is formed using the electron transport composition ICP according to one or more embodiments of the present disclosure, the light-emitting characteristics and element lifespan characteristics of a display device may be improved.

In one or more embodiments, the type (or kind) of the weak acid WA is not particularly limited as long as the weak acid has a pKa of 4.75 or more. For example, the weak acid WA may include: an organic acid containing at least one carboxylic acid group (such as acetic acid, propionic acid, normal butyric acid, isobutyl acid, pentanoic acid, hexanoic acid, heptanoic acid, octanoic acid, nonanoic acid, decanoic acid, oleic acid, stearic acid, linoleic acid, and/or linolenic acid); inorganic alkalis (such as ammonium hydroxide); a compound containing a hydroxyl group (such as water); a primary amine compound (such as methyl amine, ethyl amine, propyl amine, butyl amine, hexyl amine, heptyl amine, octyl amine, nonyl amine, decyl amine, dodecyl amine, oleyl amine, and/or aryl amine); a secondary amine compound (such as dimethyl amine, diethyl amine, dibutyl amine, dihexyl amine, diheptyl amine, methyl ethyl amine, and/or ethyl butyl amine); a tertiary amine compound (such as trimethyl amine, triethyl amine, tributyl amine, trioctyl amine, tridecyl amine, and/or N,N-dimethylaniline); an alcohol amine compound (such as monoethanol amine, diethanol amine, and/or triethanol amine); a cyclic amine compound (such as pyrrole, piperidine, and/or imidazole); a substituted or unsubstituted alkane having 1 to 30 carbon atoms; a substituted or unsubstituted cycloalkane having 1 to 30 ring-forming carbon atoms; and/or a substituted or unsubstituted alkyne having 2 to 30 carbon atoms.

In one or more embodiments, the mass ratio of the photoacid generator PG to the weak acid WA may be appropriately (or suitably) adjusted depending on the type (or kind) of material, but for example may be about 0.01:1 to about 100:1. When the mass ratio of the photoacid generator PG to the weak acid WA satisfies the above range, a stable (or suitable) reaction effect between the metal oxides MO and hydrogen ions (H⁺) may be obtained, so that the surface modification characteristics of the metal oxide MO may be improved, and the dispersion stability of the metal oxide MO may be improved, thereby making it possible to form an excellent (or improved) thin film. In one or more embodiments, the weak acid WA in the electron transport composition ICP may be omitted depending on process conditions and/or material types (or kinds).

In one or more embodiments, acids formed by the decomposition of the photoacid generator PG may form conjugate bases after releasing hydrogen ions (H⁺). In the present specification, the term “conjugate base” may be defined as a deprotonated form of an acid. The conjugate base of the acid generated by the decomposition of the photoacid generator PG may vary depending on the type (or kind) of the photoacid generator PG to be used. For example, the conjugate base of the acid generated by the decomposition of the photoacid generator PG may be any one selected from the group consisting of halogen ions (such as F⁻, Cl⁻, Br⁻, and/or I⁻), substituted or unsubstituted sulfonic acid ions, (N(CF₃)₂)⁻, (N(C₂F₅)₂)⁻, (N(C₄F₉)₂)⁻, (C(CF₃)₃)⁻, (C(C₂F₅)₃)⁻, (C(C₄F₉)₃)⁻, BF₄⁻, AsF₆⁻, and PF₆⁻. However, one or more embodiments of the present disclosure are not limited thereto.

In one or more embodiments, the conjugate base of the acid generated by the decomposition of the photoacid generator PG may be represented by Formula 3 or

Formula 4 below:

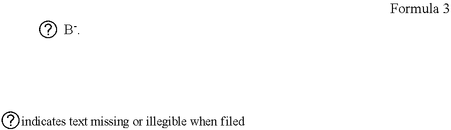

In Formula 3, B may be a halogen atom.

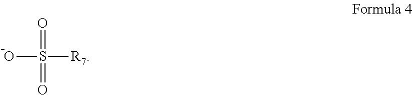

In Formula 4, R₇ may be a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

The conjugate base of the acid generated by the decomposition of the photoacid generator PG according to one or more embodiments may diffuse from the electron transport region ETR to the interface between the electron transport region ETR and the light-emitting layer EML. The conjugate base diffused to the interface between the electron transport region ETR and the light-emitting layer EML may be adsorbed onto the surfaces of the quantum dots QD included in the light-emitting layer EML, so that a passivation effect may be achieved. For example, halogen ions such as Cl⁻ formed from the photoacid generator PG may be adsorbed by (e.g., into) defects present on the surfaces of the quantum dots QD included in the light-emitting layer EML, so that a passivation effect may be achieved.

In comparable devices, a light-emitting element including quantum dots may be continuously exposed to moisture and/or oxygen during manufacturing and driving of the element, and as a result, the element is highly likely to be deteriorated. For example, when quantum dots are exposed to oxygen for a long period of time, defects that are trap states may be formed on the surface of the quantum dots. In this case, because charges in the light-emitting element are trapped and quenched, the efficiency and lifespan of the light-emitting element may decrease. The light-emitting element of the present disclosure includes a light-emitting layer having quantum dots as a light-emitting material, and may form an electron transport region disposed adjacent to the light-emitting layer using an electron transport composition according to one or more embodiments, so that the passivation effect of quantum dots may be achieved, thus resulting in improvement in the luminous efficiency and lifespan characteristics of the light-emitting element.

In one or more embodiments, the mass ratio of the photoacid generator PG to the metal oxide MO may be about 0.0001:1 to about 0.05:1. When the mass ratio of the photoacid generator PG to the metal oxide MO does not satisfy the above-described range, the surface modification performance of the metal oxide MO by the photoacid generator PG may be deteriorated. The degree of surface modification of the metal oxide MO by the photoacid generator PG may be controlled by appropriately changing the ratio within the above-described range.

In one or more embodiments, the electron transport composition ICP may further include a solvent SV. The solvent SV may be an organic solvent or an inorganic solvent such as water. The organic solvent may include an aprotic solvent or a protic solvent.

The aprotic solvent may include, for example, hexane, toluene, chloroform, dimethyl sulfoxide, octane, xylene, hexadecane, cyclohexylbenzene, triethylene glycol monobutyl ether, dimethyl formamide, decane, dodecane hexadecene, cyclohexylbenzene, tetrahydronaphthalene, ethylnaphthalene, ethylbiphenyl, isopropylnaphthalene, diisopropylnaphthalene, diisopropylbiphenyl, xylene, isopropylbenzene, pentylbenzene, diisopropylbenzene, decahydronaphthalene, phenylnaphthalene, cyclohexyldecahydronaphthalene, decylbenzene, dodecylbenzene, octylbenzene, cyclohexane, cyclopentane, cycloheptane, and/or the like, but one or more embodiments of the present disclosure are not limited thereto.

The protic solvent may be a compound capable of donating at least one proton. For example, the protic solvent may be a compound containing at least one dissociable proton. For example, the protic solvent may mean a protic liquid material and/or a protic polymer. The type (or kind) of the protic solvent may include, for example, methanol, ethanol, propanol, isopropanol, ethylene glycol, propylene glycol, diethylene glycol, and/or the like, but one or more embodiments of the present disclosure are not limited thereto.

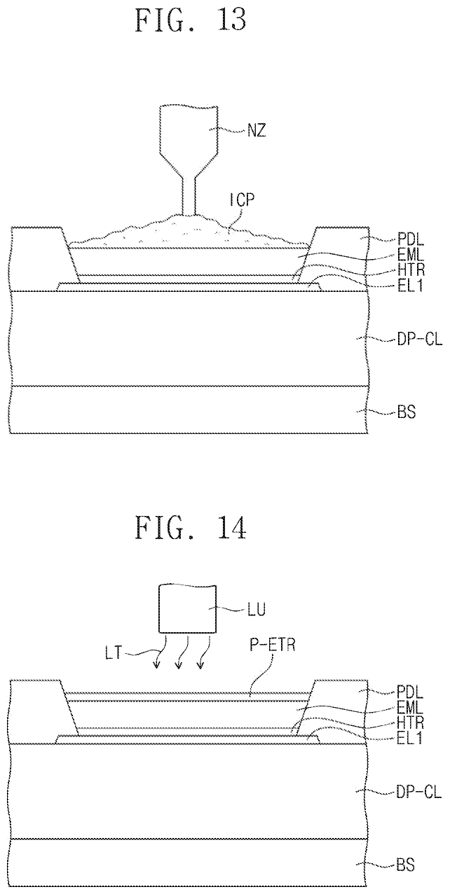

FIG. 13 schematically illustrates the act of providing of a preliminary electron transport region (S302) in a method of manufacturing a light-emitting element according to one or more embodiments. The providing of the preliminary electron transport region (S302) is an operation (e.g., act) of applying the electron transport composition ICP on the light-emitting layer EML.

In one or more embodiments, a method of applying the electron transport composition ICP on the light-emitting layer EML is not particularly limited, and suitable methods such as a spin coating method, a cast method, a LB method (Langmuir-Blodgett), an inkjet printing method, a laser printing method, and/or a laser induced thermal imaging (LITI) may be used. FIG. 13 illustrates that the electron transport composition ICP is applied between the pixel defining layers PDL through the nozzle NZ, but one or more embodiments of the present disclosure are not limited thereto.

FIG. 14 is a diagram schematically illustrating the act of providing the preliminary electron transport region P-ETR with light LT (S303) in a method of manufacturing a light-emitting element according to one or more embodiments. The providing of the preliminary electron transport region P-ETR with light LT (S303) according to one or more embodiments may be an operation (e.g., act) of inducing a reaction in which the photoacid generator PG is decomposed by irradiating the preliminary electron transport region P-ETR with light LT.

Referring to FIG. 14, the light LT emitted from a light source LU may be provided to the preliminary electron transport region P-ETR. The photoacid generator PG included in the preliminary electron transport region P-ETR may be decomposed through light irradiation to generate an acid. The light LT may include an ultraviolet light. For example, the light LT may have a center wavelength of about 250 nm to about 450 nm.

While FIGS. 13 and 14 illustrate that the hole transport region HTR and the electron transport region ETR are each provided between the pixel defining layers PDL, one or more embodiments of the present disclosure are not limited thereto. The hole transport region HTR and the electron transport region ETR may be each provided as a common layer so as to overlap the pixel defining layers PDL.

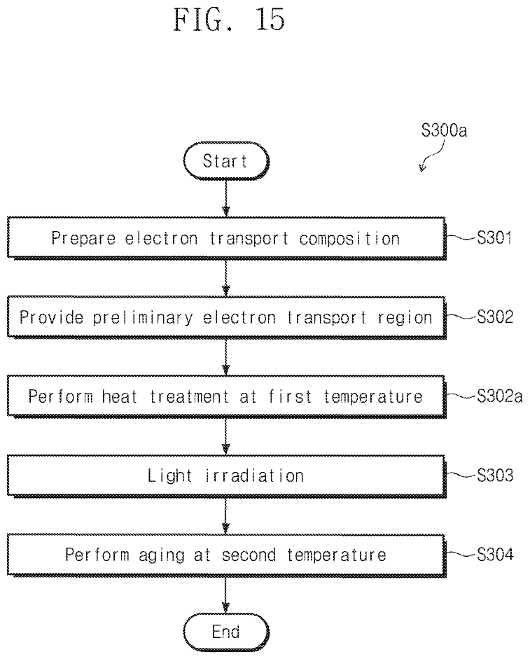

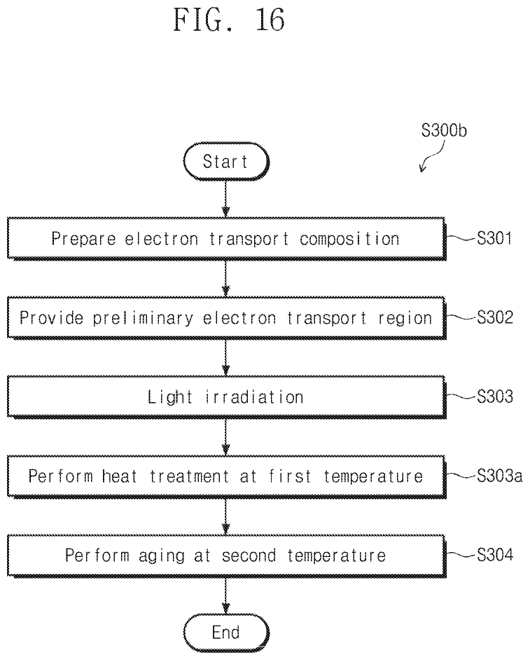

FIGS. 15 and 16 are flowcharts illustrating the forming of the electron transport regions (S300a, S₃₀₀b) in a method of manufacturing a light-emitting element according to one or more embodiments. FIGS. 15 and 16 are flowcharts different from the flowchart of FIG. 11 for forming of the electron transport region on the light-emitting layer (S300). Hereinafter, a method of forming an electron transport region according to one or more embodiments will be described in more detail with reference to FIGS. 15 and 16. Descriptions of the same contents or elements as those provided with reference to FIGS. 10 to 14 will not be provided again, but the following description will be mainly focused on differences.

The forming of the electron transport regions (S300a, S₃₀₀b) according to one or more embodiments illustrated in FIGS. 15 and 16 are different from the forming of the electron transport region (S300) described with reference to FIGS. 10 to 14 in that the former further includes performing heat treatment at a first temperature and performing aging at a second temperature.

The performing of heat treatment at the first temperature (S302a, S₃₀₃a) may change in a process sequence depending on a material included in the electron transport composition. The performing of heat treatment at the first temperature (S302a, S₃₀₃a) may be operations of performing heat treatment at the first temperature for a predetermined or set time. An unnecessary residual solvent may be removed through the heat treatments at the first temperature (S302a, S₃₀₃a), and thus a uniform (or substantially uniform) thin film may be formed. In one or more embodiments, the first temperature is not particularly limited, but may be about 100° C. to about 150° C., for example, about 110° C. to about 145° C. However, one or more embodiments of the present disclosure are not limited thereto, and the temperature and time of the heat treatment at the first temperature may be appropriately (or suitably) selected according to the type (or kind) and capacity of the material.

Referring to FIG. 15, in the forming of the electron transport region (S300a) according to one or more embodiments, performing heat treatment at the first temperature (S302a) may be performed before the irradiating of the preliminary electron transport region with light (S303). For example, the forming of the electron transport region (S300a) according to one or more embodiments may include preparing an electron transport composition (S301), providing a preliminary electron transport region (S302), performing heat treatment at the first temperature (S302a), irradiating the preliminary electron transport region with light (S303), and performing aging at the second temperature (S304).

In one or more other embodiments, referring to FIG. 16, the heat-treatment at a first temperature (S303a) may be performed after the irradiating of the preliminary electron transport region with light (S303). For example, the forming of an electron transport region (S300b) according to one or more embodiments may include preparing an electron transport composition (S301), providing a preliminary electron transport region (S302), irradiating the preliminary electron transport region with light (S303), performing heat treatment at a first temperature (S303a), and performing aging at a second temperature (S304).

In the forming of the electron transport regions (S300a, S₃₀₀b) according to one or more embodiments of the present disclosure, the degree of interaction between the hydrogen ions formed from the photoacid generator and the metal oxide may be adjusted by performing aging at the second temperature (S304). In one or more embodiments, the second temperature may be lower than the above-described first temperature range, for example, may be about 50° C. to about 95° C., for example, about 60° C. to about 85° C. The aging at the second temperature (S304) may mean stabilizing the optical characteristics of the preliminary electron transport region by continuously exposing the preliminary electron transport region, which has been subjected to light irradiation, to light of a certain or set intensity with a certain or set wavelength. In one or more embodiments, conditions such as wavelength, intensity, and/or exposure time of light in the aging at the second temperature (S304) may be appropriately (or suitably) selected depending on the type (or kind) of material. The aging at the second temperature (S304) according to one or more embodiments is a process for improving the optical characteristics of the electron transport region, so that the luminous efficiency of the light-emitting element may be further improved through the aging. In one or more embodiments, the aging may be omitted.

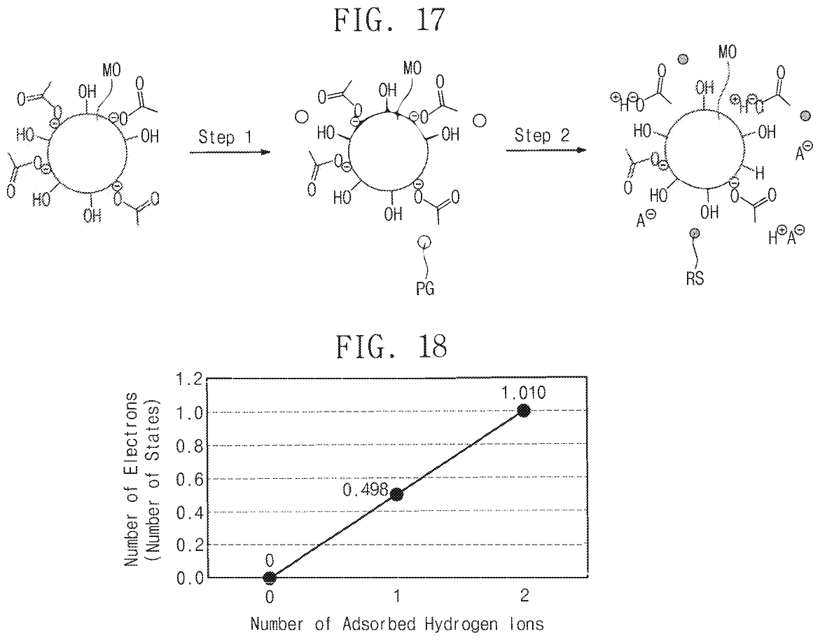

FIG. 17 is a diagram illustrating a reaction occurring in an electron transport composition. FIG. 17 exemplarily illustrates that the surface of the metal oxide is modified through hydrogen ions (H⁺) formed by decomposition of a photoacid generator in the electron transport composition according to one or more embodiments.

<Step 1> and <Step 2> illustrated in FIG. 17 respectively represent an operation (e.g., act) of providing a photoacid generator PG to a solvent containing a metal oxide MO to prepare an electron transport composition ICP, and an operation (e.g., act) of forming an acid and a residue RS through decomposition of the photoacid generator PG after irradiating the electron transport composition ICP with light.

In FIG. 17, the photoacid generator PG may be decomposed after light irradiation to form the acid and the residue RS. The surface of the metal oxide MO may be modified by hydrogen ions (H⁺) released by the acid. For example, the hydrogen ions (H⁺) may be adsorbed onto the surface of the metal oxide MO and/or may remove an acetate group adsorbed onto the surface of the metal oxide MO. In one or more embodiments, thermal equilibrium may be achieved through the aging after light irradiation, and accordingly, the degree of surface modification of the metal oxide MO may be controlled.

When the metal oxide MO surface-modified by the photoacid generator PG according to one or more embodiments is used in the light-emitting element, the degree of interference with charge injection may be mitigated. For example, a light-emitting element including the metal oxide MO, the surface of which is modified by the photoacid generator PG, may have improved charge transfer characteristics. Meanwhile, a conjugate base (A⁻) of the acid and the residue RS, resulting from the decomposition of the photoacid generator PG, may remain in the electron transport region after manufacture of an element. However, one or more embodiments of the present disclosure are not limited thereto. For example, the conjugate base (A⁻) of the acid and the residue RS, resulting from the decomposition of the photoacid generator PG, may be removed after the irradiating of the preliminary electron transport region with light (S303). For example, after the irradiating of the preliminary electron transport region with light (S303), washing the residue may be further performed. The conjugate base (A⁻) of the acid and the residue RS, resulting from the decomposition of the photoacid generator PG, may be mostly removed in the washing, but some of the conjugate base and the residue may remain in the electron transport region.

FIG. 18 is a graph showing a change in the degree of n-doping according to the number of hydrogen ions adsorbed onto the surface of a metal oxide according to one or more embodiments. FIG. 18 illustrates the result of integrating the density of states below the Fermi level in a density of state (DOS) graph.

Referring to FIG. 18, it may be seen that when one hydrogen ion is adsorbed onto the surface of the metal oxide, the number of electrons increases to 0.498, and when two hydrogen ions are adsorbed onto the surface of the metal oxide, the number of electrons increases to 1.010. This indicates that the Fermi level moves closer to the conduction band (CB) as the number of hydrogen ions adsorbed onto the metal oxide increases, so that the metal oxide may be n-doped by increasing the number of electrons acting as donors. In addition, as the number of adsorbed hydrogen ions onto the metal oxide increases, the amount of increase in current density may increase. As a result, when the metal oxide, according to one or more embodiments, of which the surface is modified by hydrogen ions, is included in the electron transport region, the current density of the light-emitting element is increased, so that the luminous efficiency and lifespan of the display device may be improved.

The electron transport composition according to one or more embodiments of the present disclosure may exhibit the effect of n-type doping of the metal oxide by including the metal oxide and the photoacid generator. For example, the photoacid generator included in the electron transport composition according to one or more embodiments may slowly generate an acid after light irradiation. The acid generated by decomposition of photoacid generator may bring about an effect of n-doping the metal oxide by removing an acetate group derived from a metal oxide precursor and/or by being adsorbed to an oxygen atom of the metal oxide. Accordingly, when the electron transport region is formed by applying the electron transport composition according to one or more embodiments, the current density in the element may increase, and the luminous efficiency and lifespan of the display device may be improved.

An electron transport composition according to one or more embodiments of the present disclosure includes a metal oxide and a photoacid generator and may thus be used as an electron transport region material capable of exhibiting an improved luminous efficiency and lifespan characteristics.

A light-emitting element according to one or more embodiments of the present disclosure, includes: an electron transport region having a metal oxide; and an acid and a conjugate base of the acid which are formed through decomposition of a photoacid generator, and may thus exhibit improved luminous efficiency and lifespan characteristics.

A method of manufacturing a light-emitting element according to one or more embodiments of the present disclosure may provide a light-emitting element having an improved luminous efficiency and lifespan characteristics by applying an electron transport composition containing a metal oxide and a photoacid generator.

Although embodiments of the present disclosure have been described, it is understood that the present disclosure should not be limited to these embodiments but that various changes and modifications may be made by one ordinary skilled in the art within the spirit and scope of the present disclosure as hereinafter claimed. Accordingly, the technical scope of the present disclosure should not be limited to the contents described in the detailed description of the specification, but should be determined by the following claims and their equivalents.

What is claimed is:

1. An electron transport composition comprising:
a metal oxide; and
a photoacid generator,
wherein the photoacid generator comprises at least one of a halogenated triazine-based compound or an oxime sulfonate-based compound.

2. The electron transport composition of claim 1, wherein the photoacid generator is represented by Formula 1 or Formula 2 below: 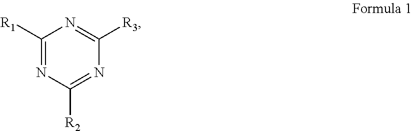
wherein, in Formula 1, R₁ to R₃ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least any one selected from among R₁ to R₃ is CX₃, and
X is a halogen atom: 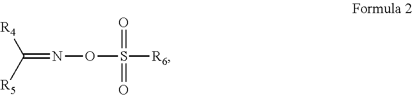
and
wherein, in Formula 2, R₄ and R₅ are each independently a hydrogen atom, a deuterium atom, a halogen atom, a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and
R₆ is a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

3. The electron transport composition of claim 1, wherein the metal oxide comprises at least any one selected from among silicon, aluminum, zinc, indium, gallium, yttrium, germanium, scandium, titanium, tantalum, hafnium, zirconium, cerium, molybdenum, nickel, chromium, iron, niobium, tungsten, tin, copper, and mixtures thereof.

4. The electron transport composition of claim 1, wherein a mass ratio of the photoacid generator to the metal oxide is about 0.0001:1 to about 0.05:1.

5. The electron transport composition of claim 1, further comprising a solvent.

6. The electron transport composition of claim 1, further comprising a weak acid having a pKa of about 4.75 or higher,
wherein a mass ratio of the photoacid generator to the weak acid is about 0.01:1 to about 100:1.

7. A method of manufacturing a light-emitting element, the method comprising:
forming a hole transport region on a first electrode;
forming a light-emitting layer on the hole transport region;
forming an electron transport region on the light-emitting layer; and
forming a second electrode on the electron transport region,
wherein the forming of the electron transport region comprises:
preparing an electron transport composition comprising a metal oxide and a photoacid generator;
forming a preliminary electron transport region by applying the electron transport composition on the light-emitting layer, and
irradiating the preliminary electron transport region with light, and
wherein the photoacid generator comprises at least one of a halogenated triazine-based compound or an oxime sulfonate-based compound.

8. The method of claim 7, wherein the forming of the electron transport region further comprises heat-treating the preliminary electron transport region at a first temperature.

9. The method of claim 8, wherein the heat-treating of the preliminary electron transport region at a first temperature is performed before or after the irradiating the preliminary electron transport region with light.

10. The method of claim 8, further comprising performing aging at a second temperature lower than the first temperature, the performing aging being after the irradiating the preliminary electron transport region with light.

11. The method of claim 7, wherein the photoacid generator is represented by Formula 1 or Formula 2 below: 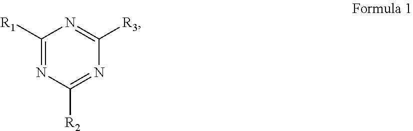
wherein, in Formula 1, R₁ to R₃ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least any one selected from among R₁ to R₃ is CX₃, and
X is a halogen atom: 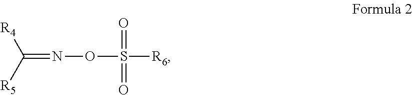
and
wherein, in Formula 2, R₄ and R₅ are each independently a hydrogen atom, a deuterium atom, a halogen atom, a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and
R₆ is a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

12. The method of claim 7, wherein the light-emitting layer comprises quantum dots.

13. The method of claim 12, wherein each of the quantum dots comprises a core and a shell around the core.

14. The method of claim 7, wherein a mass ratio of the photoacid generator to the metal oxide is about 0.0001:1 to about 0.05:1.

15. The method of claim 7, wherein the metal oxide comprises at least any one selected from among silicon, aluminum, zinc, indium, gallium, yttrium, germanium, scandium, titanium, tantalum, hafnium, zirconium, cerium, molybdenum, nickel, chromium, iron, niobium, tungsten, tin, copper, and mixtures thereof.

16. The method of claim 7, wherein the electron transport composition further comprises a weak acid having a pKa of about 4.75 or higher, and a mass ratio of the photoacid generator to the weak acid is about 0.01:1 to about 100:1.

17. A light-emitting element comprising:
a first electrode;
a hole transport region on the first electrode;
a light-emitting layer on the hole transport region, the light-emitting layer comprising quantum dots;
an electron transport region on the light-emitting layer; and
a second electrode on the electron transport region,
wherein the electron transport region comprises:
a metal oxide; and
an acid and a conjugate base of the acid which are generated by decomposition of a photoacid generator.

18. The light-emitting element of claim 17, wherein the conjugate base is represented by Formula 3 or Formula 4 below: 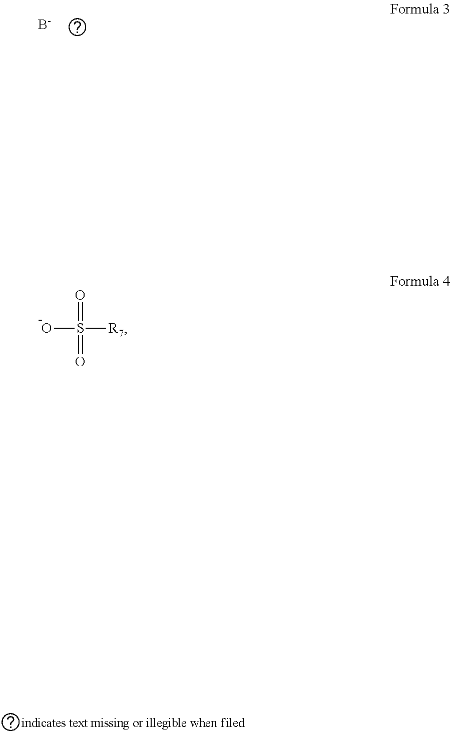
and
wherein, in Formulae 3 and 4,
B is a halogen atom, and
R₇ is a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.

19. The light-emitting element of claim 17, wherein the photoacid generator comprises at least one of a halogenated triazine-based compound or an oxime sulfonate-based compound.

20. The light-emitting element of claim 17, wherein the photoacid generator is represented by Formula 1 or Formula 2 below: 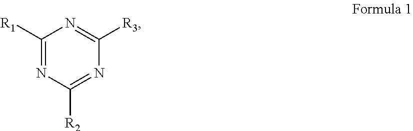
wherein, in Formula 1, R₁ to R₃ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
at least any one selected from among R₁ to R₃ is CX₃, and
X is a halogen atom: 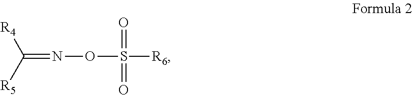
and
wherein, in Formula 2, R₄ and R₅ are each independently a hydrogen atom, a deuterium atom, a halogen atom, a substituted or unsubstituted alkyl group having 1 to 30 carbon atoms, a substituted or unsubstituted alkenyl group having 2 to 30 carbon atoms, a substituted or unsubstituted thiol group, a substituted or unsubstituted oxy group, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring, and
R₆ is a substituted or unsubstituted alkyl group having 1 to 30 carbon atoms, a substituted or unsubstituted aryl group having 6 to 30 ring-forming carbon atoms, or a substituted or unsubstituted heteroaryl group having 2 to 30 ring-forming carbon atoms.
